(19) United States
(12) Patent Application Publication
(10) Pub. No.: US 2025/0301646 A1
(43) Pub. Date: Sep. 25, 2025

(54) SEMICONDUCTOR MEMORY DEVICE

(71) Applicant: Kioxia Corporation, Tokyo (JP)

(72) Inventors: Yohei YAMAGUCHI, Yokkaichi (JP); Taichi IWASAKI, Yokkaichi (JP)

(73) Assignee: Kioxia Corporation, Tokyo (JP)

(21) Appl. No.: 18/977,544

(22) Filed: Dec. 11, 2024

(30) Foreign Application Priority Data
Mar. 21, 2024 (JP) 2024-045412

(51) Int. Cl. H10B 43/27; H01L 23/00; H01L 25/00; H01L 25/065; H01L 25/18; H10B 80/00

(52) U.S. Cl. CPC H10B 43/27; H01L 24/08; H01L 24/80; H01L 25/0657; H01L 25/18; H01L 25/50; H10B 80/00; H01L 2224/08145; H01L 2224/80895; H01L 2224/80896; H01L 2924/1431; H01L 2924/14511

(57) ABSTRACT

According to one embodiment, a semiconductor memory device includes a memory cell array; a member; and a conductor portion intersecting the member, wherein the memory cell array includes word lines on one side in a Z direction regarding a source line, the conductor portion is included in a same layer as the source line, includes a surface on an other side in the Z direction having a height substantially equivalent to a height of a surface on the other side of the source line, and the member includes a contact surrounding the word lines, and an insulating film covering a side surface of the contact from one end of the contact on the one side to a height on the one side regarding an other end of the contact.

### CROSS-REFERENCE TO RELATED APPLICATIONS

This application is based upon and claims the benefit of priority from Japanese Patent Application No. 2024-045412, filed Mar. 21, 2024, the entire contents of which are incorporated herein by reference.

### FIELD

Embodiments described herein relate generally to a semiconductor memory device.

### BACKGROUND

As a semiconductor memory device capable of storing data in a nonvolatile manner, NAND flash memory is known. In the NAND flash memory, a three-dimensional memory structure is adopted for high integration and large capacity.

### BRIEF DESCRIPTION OF THE DRAWINGS

FIG. 1 is a block diagram illustrating an example of a configuration of a memory system including a semiconductor memory device according to a first embodiment.

FIG. 2 is a circuit diagram illustrating an example of a circuit configuration of a memory cell array included in the semiconductor memory device according to the first embodiment.

FIG. 3 is a plan view illustrating an example of a planar layout of the semiconductor memory device according to the first embodiment.

FIG. 4 is a plan view illustrating an example of a planar layout of the memory cell array included in the semiconductor memory device according to the first embodiment.

FIG. 5 is a plan view illustrating an example of a planar layout of the memory cell array included in the semiconductor memory device according to the first embodiment.

FIG. 6 is a cross-sectional view taken along line VI-VI of FIG. 5, illustrating an example of a cross-sectional structure of the memory cell array of the semiconductor memory device according to the first embodiment.

FIG. 7 is a cross-sectional view taken along line VII-VII of FIG. 6, illustrating an example of a cross-sectional structure of a memory pillar of the semiconductor memory device according to the first embodiment.

FIG. 8 is a cross-sectional view illustrating an example of a cross-sectional structure in a circuit region and a wall region of the semiconductor memory device according to the first embodiment.

FIG. 9 is a cross-sectional view illustrating an example of a cross-sectional structure of a sealing portion and a member of the semiconductor memory device according to the first embodiment.

FIG. 10 is a cross-sectional view illustrating an example of a cross-sectional structure of a connection pad according to the first embodiment.

FIG. 11 is a cross-sectional view for describing an example of a method for manufacturing the semiconductor memory device according to the first embodiment.

FIG. 12 is a cross-sectional view for describing an example of a method for manufacturing the semiconductor memory device according to the first embodiment.

FIG. 13 is a cross-sectional view for describing an example of a method for manufacturing the semiconductor memory device according to the first embodiment.

FIG. 14 is a cross-sectional view for describing an example of a method for manufacturing the semiconductor memory device according to the first embodiment.

FIG. 15 is a cross-sectional view for describing an example of a method for manufacturing the semiconductor memory device according to the first embodiment.

FIG. 16 is a cross-sectional view for describing an example of a method for manufacturing the semiconductor memory device according to the first embodiment.

FIG. 17 is a cross-sectional view for describing an example of a method for manufacturing the semiconductor memory device according to the first embodiment.

FIG. 18 is a cross-sectional view for describing an example of a method for manufacturing the semiconductor memory device according to the first embodiment.

FIG. 19 is a cross-sectional view for describing an example of a method for manufacturing the semiconductor memory device according to the first embodiment.

FIG. 20 is a cross-sectional view for describing an example of a method for manufacturing the semiconductor memory device according to the first embodiment.

FIG. 21 is a cross-sectional view for describing an example of a method for manufacturing the semiconductor memory device according to the first embodiment.

FIG. 22 is a plan view illustrating an example of a planar layout of a semiconductor memory device according to a first modification of the first embodiment.

FIG. 23 is a cross-sectional view taken along line XXIII-XXIII of FIG. 22, illustrating an example of a cross-sectional structure of a sealing portion of the semiconductor memory device according to the first modification of the first embodiment.

FIG. 24 is a cross-sectional view illustrating an example of a cross-sectional structure in a circuit region and a wall region of a semiconductor memory device according to a second modification of the first embodiment.

FIG. 25 is a cross-sectional view illustrating an example of a cross-sectional structure of a sealing portion of a semiconductor memory device according to a third modification of the first embodiment.

FIG. 26 is a cross-sectional view for describing an example of a method for manufacturing the semiconductor memory device according to the third modification of the first embodiment.

FIG. 27 is a cross-sectional view for describing an example of a method for manufacturing the semiconductor memory device according to the third modification of the first embodiment.

FIG. 28 is a cross-sectional view for describing an example of a method for manufacturing the semiconductor memory device according to the third modification of the first embodiment.

FIG. 29 is a cross-sectional view for describing an example of a method for manufacturing the semiconductor memory device according to the third modification of the first embodiment.

FIG. 30 is a cross-sectional view illustrating an example of a cross-sectional structure of a sealing portion of a semiconductor memory device according to a fourth modification of the first embodiment.

FIG. 31 is a cross-sectional view for describing an example of a method for manufacturing the semiconductor memory device according to the fourth modification of the first embodiment.

FIG. 32 is a cross-sectional view illustrating an example of a cross-sectional structure of a memory cell array of a semiconductor memory device according to a second embodiment.

FIG. 33 is a cross-sectional view illustrating an example of a cross-sectional structure in a circuit region and a wall region of the semiconductor memory device according to the second embodiment.

FIG. 34 is a cross-sectional view for describing an example of a method for manufacturing the semiconductor memory device according to the second embodiment.

FIG. 35 is a cross-sectional view for describing an example of a method for manufacturing the semiconductor memory device according to the second embodiment.

FIG. 36 is a cross-sectional view illustrating an example of a cross-sectional structure of a memory cell array of a semiconductor memory device according to a modification of the second embodiment.

FIG. 37 is a cross-sectional view illustrating an example of a cross-sectional structure in a circuit region and a wall region of the semiconductor memory device according to the modification of the second embodiment.

FIG. 38 is a cross-sectional view for describing an example of a method for manufacturing the semiconductor memory device according to the modification of the second embodiment.

FIG. 39 is a cross-sectional view for describing an example of a method for manufacturing the semiconductor memory device according to the modification of the second embodiment.

FIG. 40 is a plan view illustrating an example of a planar layout of a semiconductor memory device according to another embodiment.

FIG. 41 is a cross-sectional view taken along line XLI-XLI of FIG. 40, illustrating an example of a cross-sectional structure in a circuit region and a wall region of the semiconductor memory device according to another embodiment.

FIG. 42 is a cross-sectional view for describing an example of a method for manufacturing the semiconductor memory device according to another embodiment.

FIG. 43 is a cross-sectional view illustrating an example of a cross-sectional structure of a sealing portion and a member of a semiconductor memory device according to another embodiment.

### DETAILED DESCRIPTION

In general, according to one embodiment, a semiconductor memory device includes a substrate that includes a first region and a second region provided so as to surround an outer periphery of the first region; a memory cell array that is provided in the first region; a first member that is provided in the second region; and a first conductor portion that is provided so as to intersect the first member in the second region, wherein the memory cell array includes a source line provided above the substrate, a plurality of word lines provided apart from each other in a first direction above the substrate and on one side in the first direction intersecting a surface of the substrate with respect to the source line, and a memory pillar provided to extend in the first direction so as to intersect the word lines and having one end in the first direction coupled to the source line, the first conductor portion is included in a same layer as the source line, includes a surface on an other side in the first direction having a height substantially equivalent to a height of a surface on the other side in the first direction of the source line, and is electrically insulated from the source line, and the first member includes a first contact extending in the first direction so as to surround the word lines at least in a range substantially equivalent to the word lines in the first direction while being separated from the word lines, reaching the other side in the first direction with respect to a first height of the surface on the other side of the first conductor portion, and integrally provided along the first direction, and a first insulating film covering a side surface of the first contact from a second height approximately equivalent to a height of one end of the first contact on the one side in the first direction to a third height on the one side in the first direction with respect to an other end of the first contact in the first direction, and forming an end on the other side in the first direction at the third height.

Hereinafter, embodiments will be described with reference to the drawings. Note that dimensions and ratios of the drawings are not necessarily the same as actual ones. In the following description, constituent elements having substantially the same functions and configurations are denoted by the same reference numerals. In addition, in a case where elements having similar configurations are particularly distinguished from each other, different characters or numbers may be added to the end of the same reference numeral.

### 1. First Embodiment

Hereinafter, a semiconductor memory device according to a first embodiment will be described.

### 1.1 Configuration

Hereinafter, a configuration of the semiconductor memory device according to the first embodiment will be described.

### 1.1.1 Memory System

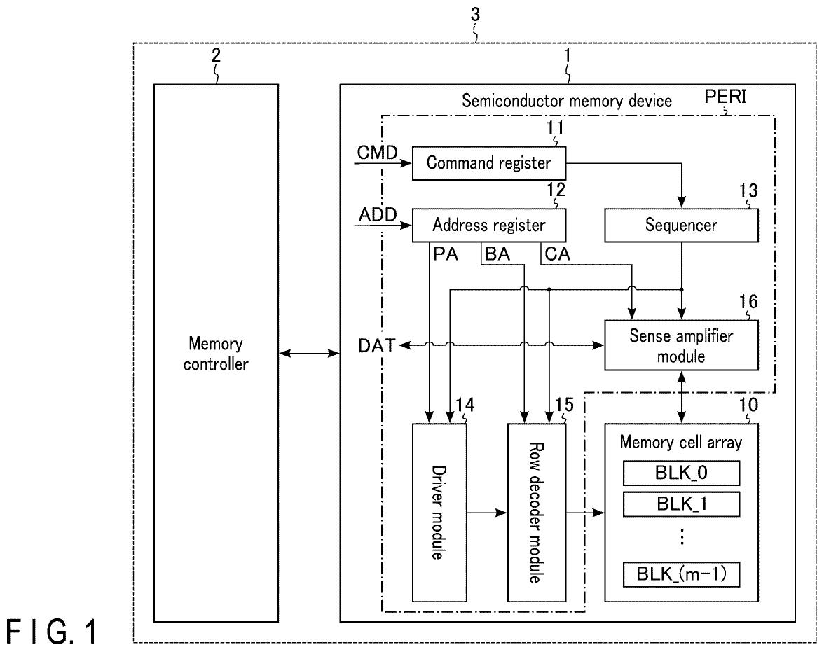

First, an example of a configuration of a memory system will be described with reference to FIG. 1. FIG. 1 is a block diagram illustrating an example of a configuration of a memory system including the semiconductor memory device according to the first embodiment.

A memory system 3 is, for example, a solid state drive (SSD) or an SD™ card. The memory system 3 is coupled to, for example, an external host device, which is not illustrated. The memory system 3 stores data from the host device. In addition, the memory system 3 reads data to the host device.

The memory system 3 includes, for example, a semiconductor memory device 1 and a memory controller 2.

The semiconductor memory device 1 is, for example, NAND flash memory. The semiconductor memory device 1 stores data in a nonvolatile manner. Hereinafter, a case where the semiconductor memory device 1 is NAND flash memory will be described as an example.

The memory controller 2 includes, for example, an integrated circuit such as a system on a chip (SoC). The memory controller 2 writes data to the semiconductor memory device 1 based on, for example, a request from the host device. In addition, the memory controller 2 reads data from the semiconductor memory device 1 based on, for example, a request from the host device. In addition, the memory controller 2 transmits data read from the semiconductor memory device 1 to the host device.

Communication between the semiconductor memory device 1 and the memory controller 2 conforms to, for example, a single data rate (SDR) interface, a toggle double data rate (DDR) interface, or an open NAND flash interface (ONFI).

### 1.1.2 Semiconductor Memory Device

Subsequently, an internal configuration of the semiconductor memory device 1 will be described with reference to FIG. 1. The semiconductor memory device 1 includes, for example, a memory cell array 10 and a peripheral circuit PERI. The peripheral circuit PERI includes, for example, a command register 11, an address register 12, a sequencer 13, a driver module 14, a row decoder module 15, and a sense amplifier module 16.

The memory cell array 10 includes a plurality of blocks BLK0 to BLK(m−1) (m is an integer of 2 or more). The block BLK is a set of a plurality of memory cells capable of storing data in a nonvolatile manner. The block BLK is used, for example, as a data erasing unit. In addition, a plurality of bit lines and a plurality of word lines are provided in the memory cell array 10. One memory cell is associated with, for example, one bit line and one word line.

The command register 11 stores a command CMD received by the semiconductor memory device 1 from the memory controller 2. The command CMD includes, for example, an instruction for causing the sequencer 13 to execute a read operation, a write operation, an erase operation, and the like.

The address register 12 stores address information ADD received by the semiconductor memory device 1 from the memory controller 2. The address information ADD includes, for example, a page address PA, a block address BA, and a column address CA. For example, the page address PA, the block address BA, and the column address CA are used to select the word line, the block BLK, and the bit line, respectively.

The sequencer 13 controls the entire operation of the semiconductor memory device 1. The sequencer 13 executes a read operation, a write operation, and an erase operation based on the command CMD stored in the command register 11.

The driver module 14 generates voltages to be used in a read operation, a write operation, an erase operation, and the like. Then, the driver module 14 applies the generated voltage to a signal line corresponding to the selected word line based on, for example, the page address PA held in the address register 12.

The row decoder module 15 selects one block BLK in the corresponding memory cell array 10 based on the block address BA held in the address register 12. Then, the row decoder module 15 transfers, for example, the voltage applied to the signal line corresponding to the selected word line to the selected word line in the selected block BLK.

The sense amplifier module 16 transfers write data DAT received from the memory controller 2 to the memory cell array 10 in the write operation. In addition, the sense amplifier module 16 executes determination of data stored in the memory cell based on the voltage of the bit line in the read operation. The sense amplifier module 16 transfers the result of the determination to the memory controller 2 as read data DAT.

### 1.1.3 Circuit Configuration of Memory Cell Array

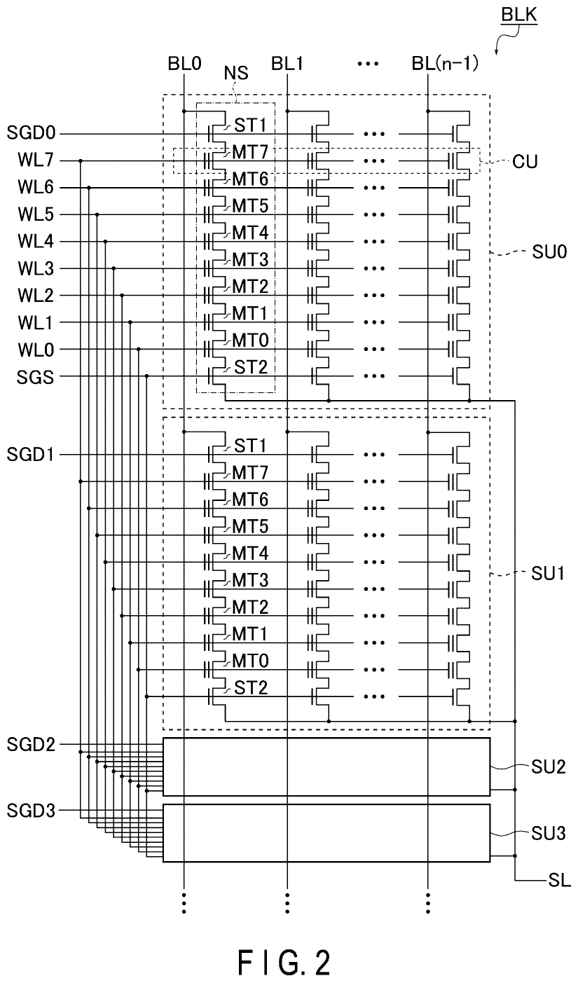

An example of a circuit configuration of the memory cell array 10 will be described with reference to FIG. 2. FIG. 2 is a circuit diagram illustrating an example of a circuit configuration of a memory cell array included in the semiconductor memory device according to the first embodiment. FIG. 2 illustrates one block BLK among the plurality of blocks BLK included in the memory cell array 10. In the example illustrated in FIG. 2, the block BLK includes four string units SU0, SU1, SU2, and SU3.

Each string unit SU includes a plurality of NAND strings NS respectively associated with bit lines BL0 to BL(n−1) (n is an integer of 2 or more). Each NAND string NS includes, for example, memory cell transistors MT0 to MT7 and select transistors ST1 and ST2. Each of the memory cell transistors MT0 to MT7 includes a control gate and a charge storage film. Each of the memory cell transistors MT0 to MT7 stores data in a nonvolatile manner. The select transistors ST1 and ST2 are used to select the string unit SU for various operations. Note that, in the following description, in a case where the bit lines BL0 to BL(n−1) are not distinguished, each of the bit lines BL0 to BL(n−1) is simply referred to as a bit line BL. In addition, in a case where the memory cell transistors MT0 to MT7 are not distinguished, each of the memory cell transistors MT0 to MT7 is simply referred to as a memory cell transistor MT.

In each NAND string NS, the memory cell transistors MT0 to MT7 are coupled in series. One end of the select transistor ST1 is coupled to the bit line BL associated with the select transistor ST1. The other end of the select transistor ST1 is coupled to one end of the memory cell transistors MT0 to MT7 coupled in series. One end of the select transistor ST2 is coupled to the other end of the memory cell transistors MT0 to MT7 coupled in series. The other end of the select transistor ST2 is coupled to a source line SL.

In the same block BLK, the control gates of the memory cell transistors MT0 to MT7 are coupled to word lines WL0 to WL7, respectively. The gates of the select transistors ST1 in the string units SU0 to SU3 are coupled to select gate lines SGD0 to SGD3, respectively. On the other hand, the gates of the plurality of select transistors ST2 are commonly coupled to a select gate line SGS. However, it is not limited thereto, and the gates of the plurality of select transistors ST2 may be coupled to a plurality of select gate lines SGS different for each string unit SU. Note that, in the following description, in a case where the word lines WL0 to WL7 are not distinguished, each of the word lines WL0 to WL7 is simply referred to as a word line WL. In addition, in a case where the select gate lines SGD0 to SGD3 are not distinguished, each of the select gate lines SGD0 to SGD3 is simply referred to as a select gate line SGD.

Different column addresses are allocated to the bit lines BL0 to BL(n−1). Each bit line BL is shared by NAND strings NS to which the same column address is allocated among the plurality of blocks BLK. The word lines WL0 to WL7 are provided for each block BLK. The source line SL is shared, for example, among the plurality of blocks BLK.

A set of the plurality of memory cell transistors MT coupled to the common word line WL in one string unit SU is referred to as, for example, a cell unit CU. For example, the storage capacity of the cell unit CU including the plurality of memory cell transistors MT each storing 1-bit data is defined as “1-page data”. The cell unit CU can have a storage capacity of 2-page data or more according to the number of bits of data stored in the memory cell transistor MT.

Note that the circuit configuration of the memory cell array 10 is not limited to the configuration described above. For example, the number of string units SU included in each block BLK may be any number. The number of the memory cell transistors MT and the number of the select transistors ST1 and ST2 included in each NAND string NS may be any number.

### 1.1.4 Structure of Semiconductor Memory Device

An example of a structure of the semiconductor memory device 1 according to the first embodiment will be described.

In the following description, an X direction is substantially parallel to a semiconductor substrate of the semiconductor memory device 1. The X direction corresponds to the extending direction of the word line WL. A Y direction is substantially parallel to the semiconductor substrate and orthogonal to the X direction. The Y direction corresponds to the extending direction of the bit line BL. A Z1 direction and a Z2 direction are substantially perpendicular to the semiconductor substrate. The Z1 direction corresponds to a direction from the semiconductor substrate toward an electrode pad of the semiconductor memory device 1. The Z2 direction corresponds to a direction from the electrode pad toward the semiconductor substrate. Note that, in a case where the Z1 direction and the Z2 direction are not distinguished, each of the Z1 direction and the Z2 direction is simply referred to as a Z direction. Hereinafter, a Z2 direction side with respect to a certain constituent element is also referred to as one side in the Z direction (or simply one side), and a Z1 direction side is also referred to as the other side in the Z direction (or simply the other side). In addition, a surface of a certain constituent element on an electrode pad side is referred to as the first surface, and a surface of a certain constituent element on a semiconductor substrate side is referred to as the second surface. The first surface and the second surface can also be referred to as a surface on the other side in the Z direction and a surface on one side in the Z direction, respectively.

### 1.1.4.1 Planar Configuration of Semiconductor Memory Device

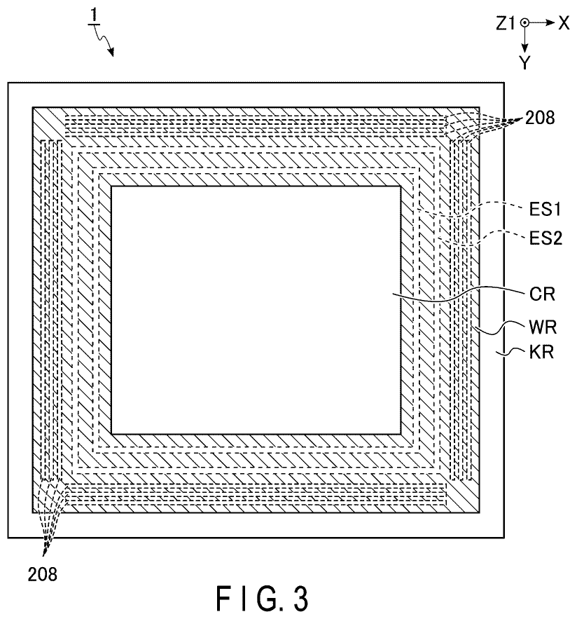

An example of a planar configuration of the semiconductor memory device 1 will be described with reference to FIG. 3. FIG. 3 is a plan view illustrating an example of a planar layout of the semiconductor memory device according to the first embodiment.

The semiconductor memory device 1 is divided into a circuit region CR, a wall region WR, and a kerf region KR in the planar layout illustrated in FIG. 3.

The circuit region CR is, for example, a region provided with elements constituting the semiconductor memory device 1 such as the memory cell array 10, the command register 11, the address register 12, the sequencer 13, the driver module 14, the row decoder module 15, and the sense amplifier module 16. The circuit region CR is, for example, a rectangular region.

The wall region WR is, for example, a region provided so as to surround an outer periphery of the circuit region CR. In the wall region WR, one or more sealing portions ES are provided so that each surrounds the outer periphery of the circuit region CR when viewed from above. In the first embodiment, an example in which sealing portions ES1 and ES2 are provided is illustrated. In addition, in the wall region WR, a plurality of conductor layers 208 is provided so that each surrounds the outer periphery of the circuit region CR when viewed from above. Each of the plurality of conductor layers 208 may have an intermittently provided annular pattern or may have a continuously provided annular pattern. In the example of FIG. 3, a case where each of the plurality of conductor layers 208 has an intermittently provided annular pattern is illustrated. In addition, one of the sealing portions ES1 and ES2 may have an intermittently provided annular pattern. The plurality of conductor layers 208 is provided, for example, on an outer peripheral side of the semiconductor memory device 1 with respect to the sealing portions ES. In FIG. 3, a region where the sealing portions ES and each of the plurality of conductor layers 208 are provided is indicated by dotted lines.

The sealing portions ES are structural bodies capable of releasing charges generated inside and outside the wall region WR to the semiconductor substrate. Each sealing portion ES suppresses accumulation of charges that may occur at the time of etching, for example, in a manufacturing process of the semiconductor memory device 1. In addition, each sealing portion ES can function as a crack stopper or an edge seal. That is, in a case where a crack occurs in a peripheral portion of a chip on which the semiconductor memory device 1 is formed, each sealing portion ES suppresses the crack from reaching the inside of the semiconductor memory device 1 with respect to the sealing portion ES. In addition, each sealing portion ES suppresses permeation of moisture or the like from an outer peripheral side to the inside of the wall region WR. The configuration of the sealing portion ES will be described below.

Similarly to the sealing portions ES, the plurality of conductor layers 208 is a structural body capable of releasing charges generated inside and outside the wall region WR to the semiconductor substrate. Each of the plurality of conductor layers 208 suppresses accumulation of charges that may occur at the time of etching, for example, in a manufacturing process different from a manufacturing process in which accumulation of charges is suppressed by the sealing portions ES. A cross-sectional configuration of the plurality of conductor layers 208 will be described below.

Note that suppression of accumulation of charges by the sealing portions ES and the plurality of conductor layers 208 will be described below.

The kerf region KR is a region provided so as to surround an outer periphery of the wall region WR. The kerf region KR is located at the outermost periphery of the semiconductor memory device 1. In the kerf region KR, for example, an alignment mark used at the time of manufacturing the semiconductor memory device 1, a circuit for a performance test of the semiconductor memory device 1, and the like are provided.

### 1.1.4.2 Structure of Memory Cell Array

First, an example of a structure of the memory cell array 10 provided in the circuit region CR will be described.

### 1.1.4.2.1 Overall Configuration of Memory Cell Array

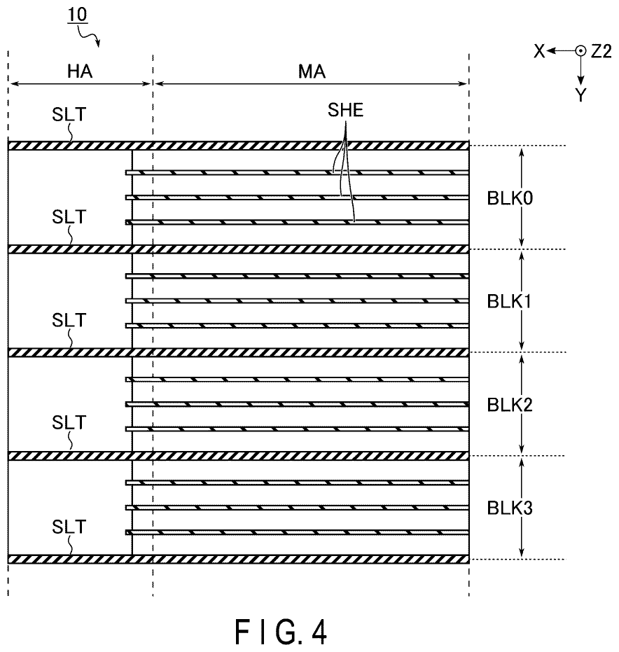

An overall configuration of the memory cell array 10 will be described with reference to FIG. 4. FIG. 4 is a plan view illustrating an example of a planar layout of the memory cell array included in the semiconductor memory device according to the first embodiment. In FIG. 4, regions corresponding to the four blocks BLK0 to BLK3 are illustrated.

The memory cell array 10 includes a stack wiring structure and a plurality of members SLT and SHE. The stack wiring structure includes the select gate lines SGD and SGS and the word lines WL. The stack wiring structure is a structure stacked along the Z direction according to the number of select gate lines SGD and SGS and word lines WL stacked. Note that, in the following description, the select gate lines SGD and SGS and the word lines WL are also collectively referred to as stack wiring.

The stack wiring structure is provided over a memory region MA and a lead-out region HA in the X direction, for example.

The memory region MA is a region in which data is substantially stored.

The lead-out region HA is a region used for coupling the stack wiring and the peripheral circuit PERI such as the row decoder module 15.

Each member SLT extends in the X direction. Each member SLT traverses the stack wiring structure across the memory region MA and the lead-out region HA in the X direction. Each member SLT has, for example, a structure in which an insulator or a plate-like contact is embedded. Each member SLT segments pieces of stack wiring adjacent to each other via the member SLT. A region partitioned by the plurality of members SLT corresponds to one block BLK. Note that, in the following description, an end of the blocks BLK0 to BLK3 on a block BLK0 side along the Y direction is referred to as one end in the Y direction.

Each member SHE extends in the X direction. In the first embodiment, a case where three members SHE are provided between adjacent members SLT will be described. Each member SHE traverses the stack wiring structure across the memory region MA in the X direction. Each member SHE has, for example, a structure in which an insulator is embedded. Each member SHE segments the adjacent select gate lines SGD via the member SHE, for example. Each of the regions partitioned by the plurality of members SLT and SHE corresponds to one string unit SU.

In the memory cell array 10, for example, the planar layout illustrated in FIG. 4 is repeatedly disposed in the Y direction.

Note that the planar layout of the memory cell array 10 is not limited to the layout described above. For example, the number of members SHE disposed between the adjacent members SLT can be designed to be an arbitrary number according to the number of string units SU.

### 1.1.4.2.2 Structure of Memory Cell Array in Memory Region

A structure in the memory region MA of the memory cell array 10 will be described.

### 1.1.4.2.2.1 Planar Structure

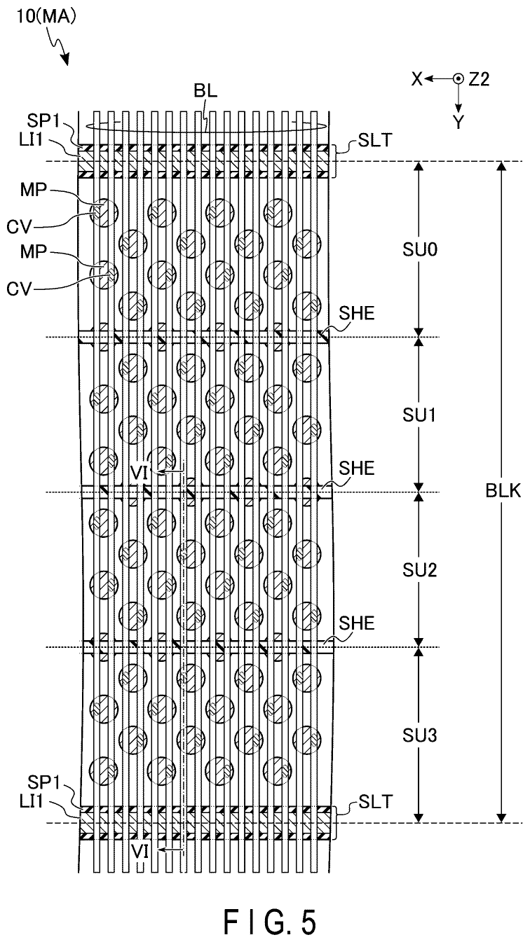

A planar structure in the memory region MA of the memory cell array 10 will be described with reference to FIG. 5. FIG. 5 is a plan view illustrating an example of a planar layout of the memory cell array included in the semiconductor memory device according to the first embodiment.

In the memory region MA, the memory cell array 10 includes a plurality of memory pillars MP, a plurality of contacts CV, and a plurality of bit lines BL. In addition, each member SLT includes a contact LI1 and a spacer SP1.

Each memory pillar MP functions as, for example, one NAND string NS. The plurality of memory pillars MP is disposed in, for example, 19 rows in a staggered manner in a region between two adjacent members SLT. Then, for example, one member SHE overlaps the memory pillar MP of the fifth row, the memory pillar MP of the 10th row, and the memory pillar MP of the 15th row from one end side in the Y direction.

Each of the plurality of bit lines BL extends in the Y direction. In addition, the plurality of bit lines BL is arranged in the X direction. Each bit line BL is disposed so as to overlap at least one memory pillar MP for each string unit SU. In the example of FIG. 5, each bit line BL is disposed so as to overlap two memory pillars MP for each string unit SU. One bit line BL among the plurality of bit lines BL overlapping the memory pillar MP is electrically coupled to the memory pillar MP via a contact CV. The contact CV between the memory pillar MP overlapping the member SHE and the bit line BL is omitted (not provided), for example.

The contact LI1 is a conductor having a portion provided to extend in the X direction. The spacer SP1 is an insulator provided on a side surface of the contact LI1. The contact LI1 is sandwiched by the spacer SP1. The contact LI1 and the stack wiring adjacent to the contact LI1 in the Y direction are electrically separated by the spacer SP1. As a result, the contact LI1 and the stack wiring adjacent to the contact LI1 in the Y direction are insulated from each other.

### 1.1.4.2.2.2 Cross-Sectional Structure

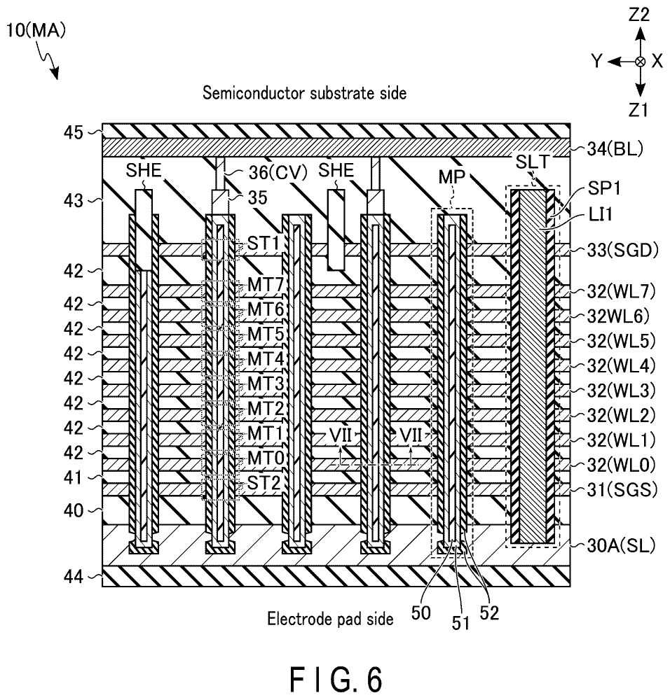

A cross-sectional structure in the memory region MA of the memory cell array 10 will be described with reference to FIG. 6. FIG. 6 is a cross-sectional view taken along line VI-VI of FIG. 5, illustrating an example of a cross-sectional structure of the memory cell array of the semiconductor memory device according to the first embodiment.

The memory cell array 10 further includes conductor layers 30A, 31, and 33, a plurality of conductor layers 32, 34, 35, and 36, insulator layers 40, 41, 43, 44, and 45, and a plurality of insulator layers 42. FIG. 6 illustrates five memory pillars MP among the plurality of memory pillars MP. In addition, FIG. 6 illustrates a case where eight conductor layers 32 and eight insulator layers 42 are included as the plurality of conductor layers 32 and the plurality of insulator layers 42, respectively. The memory cell array 10 is provided between the electrode pad and the semiconductor substrate of the semiconductor memory device 1 in the Z direction.

The conductor layer 30A is formed in, for example, a plate shape extending along an XY plane. The conductor layer 30A is used as the source line SL. The conductor layer 30A is made of a conductive material. The conductive material is, for example, an N-type semiconductor doped with impurities or a metal material.

The insulator layer 40 is stacked on the second surface of the conductor layer 30A. The conductor layer 31 is stacked on the second surface of the insulator layer 40. The conductor layer 31 is formed in, for example, a plate shape extending along the XY plane. The conductor layer 31 is used as the select gate line SGS. The conductor layer 31 contains, for example, tungsten.

The insulator layer 41 is stacked on the second surface of the conductor layer 31. On the second surface of the insulator layer 41, the eight conductor layers 32 and the eight insulator layers 42 are stacked in the order of the conductor layer 32, the insulator layers 42, . . . , the conductor layer 32, and the insulator layer 42 in the Z2 direction. The conductor layer 32 is formed in, for example, a plate shape extending along the XY plane. The eight conductor layers 32 are used as the word lines WL0 to WL7, respectively, in order from a conductor layer 31 side along the Z2 direction. The conductor layer 32 contains, for example, tungsten.

The conductor layer 33 is stacked on the second surface of the insulator layer 42 on the most one side in the Z direction among the eight insulator layers 42. The conductor layer 33 is formed in, for example, a plate shape extending along the XY plane. The conductor layer 33 is used as the select gate line SGD. The conductor layer 33 contains, for example, tungsten. The conductor layer 33 is electrically insulated for each string unit SU by, for example, the plurality of members SHE.

The insulator layer 43 is stacked on the second surface of the conductor layer 33. The conductor layer 34 is stacked on the second surface of the insulator layer 43. The conductor layer 34 is provided to extend along the Y direction. The conductor layer 34 functions as the bit line BL.

The stack structure including the conductor layers 30A, 31, 33, and 34, the eight conductor layers 32, the insulator layers 40, 41, and 43, and the eight insulator layers 42 as described above is provided so as to be surrounded by an insulator. FIG. 6 illustrates the insulator layer 44 in contact with the first surface of the conductor layer 30A and the insulator layer 45 in contact with the second surface of the conductor layer 34. Note that although not illustrated in FIG. 6, as described below, the conductor layer 30A is electrically coupled to the peripheral circuit PERI via, for example, a conductor layer on the other side with respect to the conductor layer 30A. In addition, although not illustrated in FIG. 6, as described below, the conductor layer 34 is electrically coupled to the peripheral circuit PERI via, for example, a conductor layer on one side with respect to the conductor layer 34.

On the other side of the conductor layer 34, the plurality of memory pillars MP is provided to extend along the Z direction. The plurality of memory pillars MP penetrates the conductor layers 31 and 33 and the eight conductor layers 32.

Each of the plurality of memory pillars MP includes, for example, a core member 50, a semiconductor film 51, and a stack film 52. The core member 50 is provided to extend along the Z direction. The semiconductor film 51 covers the periphery of the core member 50. The semiconductor film 51 is in contact with the conductor layer 30A. The stack film 52 covers a side surface and the first surface of the semiconductor film 51 except for a portion where the semiconductor film 51 and the conductor layer 30A are in contact with each other. The core member 50 includes an insulator such as silicon oxide. The semiconductor film 51 contains, for example, silicon. The configuration of the stack film 52 will be described below.

The conductor layer 35 is provided on the second surface of the semiconductor film 51. The conductor layer 35 functions as, for example, a columnar contact. The conductor layer 36 is provided on the second surface of the conductor layer 35. The conductor layer 35 functions as, for example, the contact CV. With the above configuration, the conductor layers 35 and 36 couple the semiconductor film 51 and the conductor layer 34. One conductor layer 35 and one conductor layer 36 are coupled to one conductor layer 34 in each of spaces partitioned by the members SLT and SHE.

The member SLT divides the conductor layers 31 to 33. The contact LI1 in the member SLT is provided along the member SLT. The second surface of the contact LI1 is located between the conductor layer 33 and the conductor layer 34. The first surface of the contact LI1 is located between the insulator layers 40 and 44. As a result, the contact LI1 is coupled to the conductor layer 30A. The contact LI1 is used, for example, as a part of the source line SL. The spacer SP1 is provided between the contact LI1 and the conductor layers 31 to 33. The contact LI1 and the conductor layers 31 to 33 are separated and insulated from each other by the spacer SP1. Note that although not illustrated in FIG. 6, the contact LI1 may include a barrier metal. That is, the contact LI1 may have a structure in which the barrier metal covers the first surface and a side surface of the member containing metal, for example.

A portion where each of the plurality of memory pillars MP intersects the conductor layer 31 functions as the select transistor ST2. A portion where each of the plurality of memory pillars MP intersects each conductor layer 32 functions as the memory cell transistor MT. A portion where each of the plurality of memory pillars MP intersects the conductor layer 33 functions as the select transistor ST1.

### 1.1.4.2.2.3 Cross-Sectional Structure of Memory Pillar

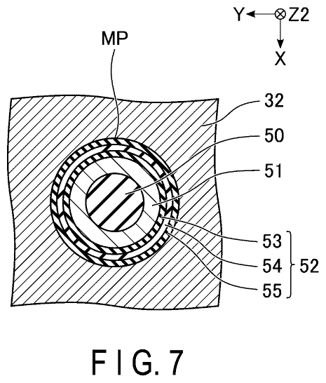

The structure of the memory pillar MP will be described with reference to FIG. 7. FIG. 7 is a cross-sectional view taken along line VII-VII of FIG. 6, illustrating an example of a cross-sectional structure of a memory pillar of the semiconductor memory device according to the first embodiment.

The stack film 52 includes a tunnel insulating film 53, a charge storage film 54, and a block insulating film 55. The tunnel insulating film 53 covers a side surface and the first surface of the semiconductor film 51 except for a portion where the semiconductor film 51 and the conductor layer 30A are in contact with each other. The charge storage film 54 covers a side surface and the first surface of the tunnel insulating film 53. The block insulating film 55 covers a side surface and the first surface of the charge storage film 54.

The tunnel insulating film 53 and the block insulating film 55 contain, for example, silicon oxide. The charge storage film 54 contains, for example, silicon nitride. The charge storage film 54 is capable of storing charges.

In the above configuration, the semiconductor film 51 functions as a channel of each of the memory cell transistors MT0 to MT7 and the select transistors ST1 and ST2. In addition, the charge storage film 54 functions as a charge storage site of the memory cell transistor MT. The semiconductor memory device 1 causes a current to flow between the conductor layers 34 and 30A (between the bit line BL and the source line SL) through the memory pillars MP and the conductor layers 35 and 36 by turning on the memory cell transistors MT0 to MT7 and the select transistors ST1 and ST2.

### 1.1.4.3 Overall Cross-Sectional Structure of Semiconductor Memory Device

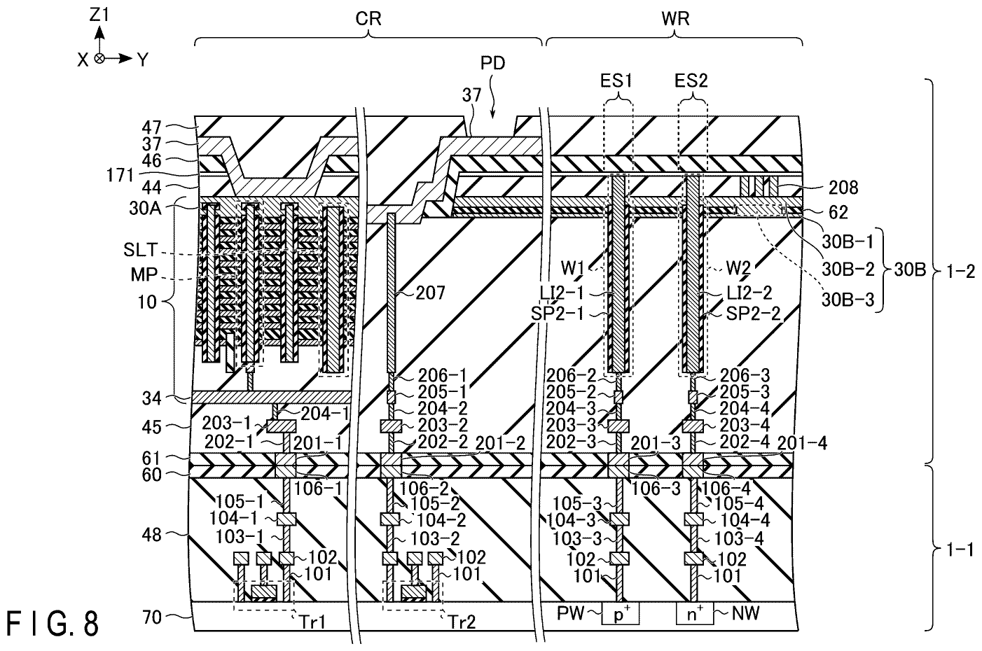

An overall cross-sectional structure of the semiconductor memory device 1 will be described with reference to FIG. 8. FIG. 8 is a cross-sectional view illustrating an example of a cross-sectional structure in a circuit region and a wall region of the semiconductor memory device according to the first embodiment. FIG. 8 illustrates a cross-sectional structure of a portion of the semiconductor memory device 1.

The semiconductor memory device 1 has a structure in which a circuit chip 1-1 and a memory chip 1-2 are bonded together.

### 1.1.4.3.1 Circuit Chip

A cross-sectional structure of the circuit chip 1-1 will be described.

The circuit chip 1-1 includes, for example, a semiconductor substrate 70, a plurality of conductor layers 101, 102, 103, 104, 105, and 106 and insulator layers 48 and 60 constituting a part of the peripheral circuit PERI. The semiconductor substrate 70 is made of, for example, a P-type semiconductor doped with impurities. Each of the plurality of conductor layers 101, 102, 103, 104, 105, and 106 functions as, for example, a columnar contact or wiring. In FIG. 8, a plurality of conductor layers 103 includes conductor layers 103-1, 103-2, 103-3, and 103-4. A plurality of conductor layers 104 includes conductor layers 104-1, 104-2, 104-3, and 104-4. A plurality of conductor layers 105 includes conductor layers 105-1, 105-2, 105-3, and 105-4. A plurality of conductor layers 106 includes conductor layers 106-1, 106-2, 106-3, and 106-4.

The insulator layer 48 is provided on the first surface of the semiconductor substrate 70. The insulator layer 48 contains, for example, silicon oxide. In the insulator layer 48, the plurality of conductor layers 101, 102, 103, 104, and 105 is provided.

On the first surface of the semiconductor substrate 70, the peripheral circuit PERI is provided in the circuit region CR. In FIG. 8, transistors Tr1 and Tr2 are illustrated as an example of a configuration included in the peripheral circuit PERI. In the following description, in a case where the transistors Tr1 and Tr2 are not distinguished, the transistors Tr1 and Tr2 are simply referred to as transistors Tr. Each transistor Tr includes a gate insulating film, a gate electrode, and a source and a drain, which are not illustrated, provided on the semiconductor substrate 70.

The semiconductor substrate 70 is provided with a P-type impurity-diffused region PW and an N-type impurity-diffused region NW in the wall region WR. Each of the P-type impurity-diffused region PW and the N-type impurity-diffused region NW may have an intermittently provided annular pattern or a continuously provided annular pattern when viewed from above.

The plurality of conductor layers 101 is provided on the first surface of the gate electrode, the source, and the drain of the transistor Tr1, the gate electrode, the source, and the drain of the transistor Tr2, the P-type impurity-diffused region PW, and the N-type impurity-diffused region NW. The plurality of conductor layers 102 is coupled to the first surfaces of the plurality of conductor layers 101, respectively.

Each of the plurality of conductor layers 103 is coupled to the first surface of the conductor layer 102 corresponding to the conductor layer 103 among the plurality of conductor layers 102. The conductor layers 103-1, 103-2, 103-3, and 103-4 are electrically coupled to the transistors Tr1 and Tr2, the P-type impurity-diffused region PW, and the N-type impurity-diffused region NW, respectively.

The conductor layers 104-1, 104-2, 104-3, and 104-4 are coupled to the first surfaces of the conductor layers 103-1, 103-2, 103-3, and 103-4, respectively.

The conductor layers 105-1, 105-2, 105-3, and 105-4 are coupled to the first surfaces of the conductor layers 104-1, 104-2, 104-3, and 104-4, respectively. The first surfaces of the plurality of conductor layers 105 are provided so as to be flush with the first surface of the insulator layer 48.

The insulator layer 60 is provided on the first surfaces of the insulator layer 48 and the plurality of conductor layers 105. The insulator layer 60 contains, for example, silicon oxide.

The plurality of conductor layers 106 is provided in the same layer as the insulator layer 60. The conductor layers 106-1, 106-2, 106-3, and 106-4 are coupled to the first surfaces of the conductor layers 105-1, 105-2, 105-3, and 105-4, respectively. The first surfaces of the plurality of conductor layers 106 are provided so as to be flush with the first surface of the insulator layer 60. The plurality of conductor layers 106 contains, for example, copper. The plurality of conductor layers 106 functions as a plurality of connection pads for electrically coupling the circuit chip 1-1 and the memory chip 1-2. The connection pad is also referred to as a bonding pad.

### 1.1.4.3.2 Memory Chip

The cross-sectional structure of the memory chip 1-2 will be continuously described with reference to FIG. 8.

The memory chip 1-2 includes, for example, a plurality of conductor layers 201, 202, 203, 204, 205, 206, and 208, conductor layers 37 and 207, insulator layers 46, 47, and 61, a member 171, the memory cell array 10, and a plurality of members W. Each of the plurality of members W includes a contact LI2 and a spacer SP2. The contact LI2 is a conductor. The spacer SP2 is, as described below, an insulator provided on a side surface portion of the contact LI2.

Each of the plurality of conductor layers 201, 202, 203, 204, 205, 206, and 208 and the conductor layer 207 functions as, for example, a columnar contact or wiring. In FIG. 8, a plurality of conductor layers 201 includes conductor layers 201-1, 201-2, 201-3, and 201-4. A plurality of conductor layers 202 includes conductor layers 202-1, 202-2, 202-3, and 202-4. A plurality of conductor layers 203 includes conductor layers 203-1, 203-2, 203-3, and 203-4. A plurality of conductor layers 204 includes conductor layers 204-1, 204-2, 204-3, and 204-4. A plurality of conductor layers 205 includes conductor layers 205-1, 205-2, and 205-3. A plurality of conductor layers 206 includes conductor layers 206-1, 206-2, and 206-3. In addition, in FIG. 8, the plurality of members W includes members W1 and W2. The member W1 includes a contact LI2-1 and a spacer SP2-1 as the contact LI2 and the spacer SP2, respectively. The member W2 includes a contact LI2-2 and a spacer SP2-2 as the contact LI2 and the spacer SP2, respectively.

In the memory chip 1-2, the insulator layer 61 is provided on the first surface of the circuit chip 1-1. The insulator layer 61 contains, for example, silicon oxide.

The plurality of conductor layers 201 is provided in the same layer as the insulator layer 61. The conductor layers 201-1, 201-2, 201-3, and 201-4 are coupled to the first surfaces of the conductor layers 106-1, 106-2, 106-3, and 106-4, respectively. The first surfaces of the plurality of conductor layers 201 are provided so as to be flush with the first surface of the insulator layer 61. The plurality of conductor layers 201 contains, for example, copper. The plurality of conductor layers 201 functions as a plurality of connection pads for electrically coupling the circuit chip 1-1 and the memory chip 1-2. With the above configuration, the circuit chip 1-1 and the memory chip 1-2 are electrically coupled by the plurality of conductor layers 106 and 201.

The insulator layer 45 is provided on the first surfaces of the insulator layer 61 and the plurality of conductor layers 201. In the insulator layer 45, the plurality of conductor layers 202, 203, 204, 205, and 206, a portion of the conductor layer 207, a portion of the memory cell array 10, a portion of the plurality of contacts LI2, and a portion of the plurality of spacers SP2 are provided.

The memory cell array 10 is provided such that the conductor layer 34 is disposed on one side in the Z direction and the conductor layer 30A is disposed on the other side in the Z direction.

The conductor layer 202-1 is provided on the first surface of the conductor layer 201-1. The conductor layer 203-1 is coupled to the first surface of the conductor layer 202-1. The conductor layer 204-1 is coupled to the first surface of the conductor layer 203-1. The first surface of the conductor layer 204-1 is coupled to the conductor layer 34. With the above configuration, the bit line BL and the transistor Tr1 are configured to be connectable.

The conductor layer 202-2 is provided on the first surface of the conductor layer 201-2. The conductor layer 203-2 is provided on the first surface of the conductor layer 202-2. The conductor layer 204-2 is provided on the first surface of the conductor layer 203-2. The conductor layer 205-1 is provided on the first surface of the conductor layer 204-2. The conductor layer 206-1 is provided on the first surface of the conductor layer 205-1. The conductor layer 207 is provided on the first surface of the conductor layer 206-1. The conductor layer 207 functions as, for example, a columnar contact. The conductor layer 207 penetrates the insulator layer 45 in the Z direction. The conductor layer 207 has, for example, a portion on the other side protruding from the insulator layer 45.

The conductor layer 37 is provided on the other side with respect to the insulator layer 45. The conductor layer 37 functions as a wiring layer. The conductor layer 37 contains, for example, aluminum. In FIG. 8, the conductor layer 37 extends in the Y direction. The conductor layer 37 includes a portion in contact with the conductor layer 30A and a portion in contact with the conductor layer 207. With the above configuration, the source line SL and the transistor Tr2 are configured to be connectable. In a portion in contact with the conductor layer 207, the conductor layer 37 is provided so as to cover, for example, a portion on the other side of the conductor layer 207 protruding from the insulator layer 45. In addition, the conductor layer 37 includes a portion exposed to the first surface of the semiconductor memory device 1. This portion functions as, for example, an electrode pad PD coupled to a device outside the semiconductor memory device 1.

In a region excluding a portion where the memory cell array 10 is provided, a conductor layer 30B is provided in a portion of the first surface of the insulator layer 45. The conductor layer 30B is included at the same height as the conductor layer 30A of the memory cell array 10. The conductor layer 30B is electrically insulated from the conductor layer 30A. An insulator layer 62 is provided inside the conductor layer 30B. In the following description, a portion of the conductor layer 30B included on one side with respect to the insulator layer 62 is referred to as a conductor portion 30B-1. In addition, in the following description, a portion of the conductor layer 30B included on the other side with respect to the insulator layer 62 is referred to as a conductor portion 30B-2. The conductor portion 30B-2 is made of, for example, an N-type semiconductor doped with impurities. The second surface of the conductor portion 30B-1 and the second surface of the conductor layer 30A are located at the same height, for example. The first surface of the conductor portion 30B-2 and the first surface of the conductor layer 30A are located at the same first height, for example. The conductor layer 30B includes a portion overlapping a region where the plurality of conductor layers 208 is provided in the Z direction. In a portion overlapping the plurality of conductor layers 208 in the Z direction, the insulator layer 62 is segmented by the conductor layer 30B. The segmenting portion of the conductor layer 30B is referred to as a conductor portion 30B-3. The conductor portions 30B-1 and 30B-2 are electrically coupled by the conductor portion 30B-3.

On the first surface of the conductor layer 30B, the plurality of conductor layers 208 is provided so as to be in contact with the conductor portion 30B-2 of the conductor layer 30B. The plurality of conductor layers 208 is made of, for example, an N-type semiconductor doped with impurities, similarly to the conductor portion 30B-2. The insulator layer 44 is provided on the first surfaces of the conductor layers 30A and 30B except for a portion of the conductor layer 30B where the plurality of conductor layers 208 is provided and a portion of the conductor layer 30A in contact with the conductor layer 37. The insulator layer 44 and the plurality of conductor layers 208 are provided at the same height. The first surface of each conductor layer 208 is configured to be flush with the first surface of the insulator layer 44. In addition, the second surface of each conductor layer 208 is configured to be flush with the second surface of the insulator layer 44. As described below, the plurality of conductor layers 208 functions as an antistatic member for releasing positive charges generated in the manufacturing process.

The conductor layer 202-3 is provided on the first surface of the conductor layer 201-3. The conductor layer 203-3 is provided on the first surface of the conductor layer 202-3. The conductor layer 204-3 is provided on the first surface of the conductor layer 203-3. The conductor layer 205-2 is provided on the first surface of the conductor layer 204-3. The conductor layer 206-2 is provided on the first surface of the conductor layer 205-2. The contact LI2-1 of the member W1 is provided on the first surface of the conductor layer 206-2. The contact LI2-1 penetrates the insulator layers 44, 45, and 62 and the conductor layer 30B in the Z direction. The first surface of the contact LI2-1 is configured to be flush with the first surface of the insulator layer 44. The second surface of the contact LI2-1 is located on one side of the second surface of the memory pillar MP, for example. The second surface of the contact LI2-1 and the second surface of the member SLT are located at the same height, for example. In addition, although not illustrated, the contact LI2-1 extends in the X direction and the Y direction in correspondence with the sealing portion ES1 of FIG. 3 so as to surround the circuit region CR. The spacer SP2-1 is provided on a side surface portion of the contact LI2-1. The spacer SP2-1 is provided in a range excluding a portion on the other side of the contact LI2-1 in the Z direction. The configurations of the contact LI2 and the spacer SP2 will be further described below. The conductor layers 201-3, 202-3, 203-3, 204-3, 205-2, and 206-2, the contact LI2-1, and the spacer SP2-1 are formed in an annular pattern when viewed from above, for example, together with the conductor layers 101 and 102 and the conductor layers 103-3, 104-3, 105-3, and 106-3 coupled to the P-type impurity-diffused region PW of the circuit chip 1-1, and function as the sealing portion ES1. Note that similarly to the contact LI1, the contact LI2-1 may have a structure in which the barrier metal covers the first surface and a side surface of the member containing metal, for example.

The conductor layer 202-4 is provided on the first surface of the conductor layer 201-4. The conductor layer 203-4 is provided on the first surface of the conductor layer 202-4. The conductor layer 204-4 is provided on the first surface of the conductor layer 203-4. The conductor layer 205-3 is provided on the first surface of the conductor layer 204-4. The conductor layer 206-3 is provided on the first surface of the conductor layer 205-3. The contact LI2-2 of the member W2 is provided on the first surface of the conductor layer 206-3. The contact LI2-2 penetrates the insulator layers 44, 45, and 62 and the conductor layer 30B in the Z direction. The first surface of the contact LI2-2 is configured to be flush with the first surface of the insulator layer 44. The second surface of the contact LI2-2 is located at the same height as the second surface of the contact LI2-1, for example. In addition, although not illustrated, similarly to the contact LI2-1, the contact LI2-2 extends in the X direction and the Y direction so as to surround the circuit region CR. The spacer SP2-2 is provided on a side surface portion of the contact LI2-2. The spacer SP2-2 is provided in a range excluding a portion on the other side of the contact LI2-1. The conductor layers 201-4, 202-4, 203-4, 204-4, 205-3, and 206-3, the contact LI2-2, and the spacer SP2-2 are formed in an annular pattern when viewed from above, for example, together with the conductor layers 101 and 102 and the conductor layers 103-4, 104-4, 105-4, and 106-4 coupled to the N-type impurity-diffused region NW of the circuit chip 1-1, and function as the sealing portion ES2. Note that the contact LI2-2 has, for example, the same structure as the contact LI2-1.

For example, the member 171 is provided on the first surfaces of the insulator layer 44, the plurality of contacts LI2, and the plurality of conductor layers 208. The member 171 is a portion of the semiconductor substrate used for forming the memory chip 1-2 in the manufacturing process as described below.

The insulator layer 46 is provided on the first surface of the member 171 to the same height as the second surface of the conductor layer 37. In addition, the insulator layer 46 is provided so as to electrically insulate the conductor layers 37 and 30B. In FIG. 8, the insulator layer 46 is provided, for example, between a portion of the conductor layer 37 in contact with the conductor layer 207 and the conductor layer 30B and the insulator layers 44 and 62.

The insulator layer 47 is provided on the first surfaces of the conductor layer 37 and the insulator layer 46 except for a portion functioning as the electrode pad PD. The insulator layer 47 functions as a passivation film. The insulator layer 47 contains, for example, silicon nitride, a resin material, or the like.

Note that FIG. 8 illustrates a case where the semiconductor memory device 1 includes the member 171, but it is not limited thereto. The semiconductor memory device 1 may not include the member 171. That is, the semiconductor substrate used for forming the memory chip 1-2 in the manufacturing process may be fully removed. In this case, the second surface of the insulator layer 46 is in contact with, for example, the first surface of the insulator layer 44, the first surfaces of the plurality of contacts LI2, and the first surfaces of the plurality of conductor layers 208.

### 1.1.4.3.3 Sealing Portion

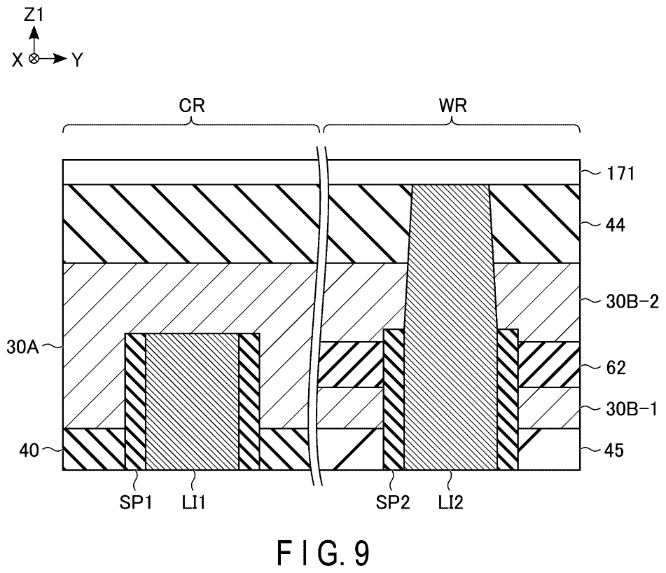

The configurations of the contact LI2 and the spacer SP2 included in the sealing portion ES of the semiconductor memory device 1 will be further described with reference to FIG. 9. FIG. 9 is a cross-sectional view illustrating an example of a cross-sectional structure of a sealing portion and a member of the semiconductor memory device according to the first embodiment. In FIG. 9, the cross-sectional structure of the portion of the contact LI2 and the spacer SP2 in the member W in the same cross section as FIG. 8 is illustrated together with the cross-sectional structure of the portion of the contact LI1 and the spacer SP1 in the member SLT.

The contact LI2 reaches the other side with respect to the first height of the first surface of the conductor portion 30B-2 in the Z direction. The spacer SP2 covers the side surface of the contact LI2 so that the contact LI2 is coupled with the conductor portion 30B-2. That is, the spacer SP2 covers the side surface of the contact LI2 from the second (fifth) height of the second surface of the contact LI2 to the third (sixth) height between the second surface of the conductor portion 30B-1 and the first surface of the conductor portion 30B-2. As a result, the contact LI2 and the conductor layer 30B are electrically coupled on the other side with respect to the end of the spacer SP2 formed at the third height on the other side in the Z direction.

### 1.1.4.3.4 Cross-Sectional Structure of Connection Pad

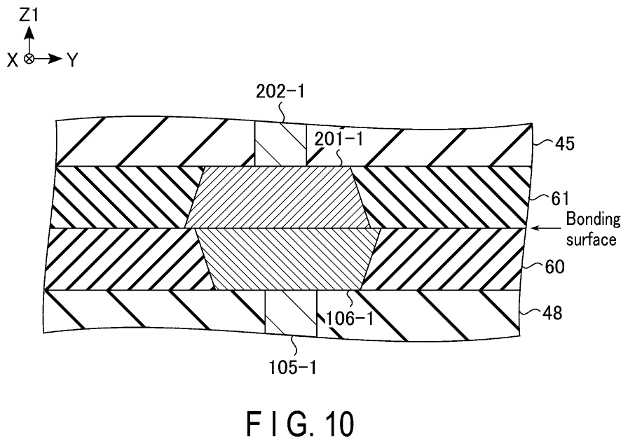

A cross-sectional structure of the connection pad will be described with reference to FIG. 10. FIG. 10 is a cross-sectional view illustrating an example of a cross-sectional structure of a connection pad according to the first embodiment. Note that, in the following, a portion where the conductor layer 106-1 and the conductor layer 201-1 are coupled will be described, but the same applies to a portion where each of the plurality of other conductor layers 106 and the conductor layer 201 corresponding to the conductor layer 106 are coupled.

In the bonding surface on which the circuit chip 1-1 and the memory chip 1-2 are bonded, the area of the conductor layer 106-1 is equal to the area of the conductor layer 201-1, for example. In a case where the conductor layers 106-1 and 201-1 are copper, the conductor layers 106-1 and 201-1 are integrated, and it may be difficult to confirm a copper boundary. However, for example, bonding can be confirmed by distortion of the shape of the bonded conductor layers 106-1 and 201-1 due to positional bonding deviation. In addition, for example, bonding can be confirmed by positional deviation of the copper barrier metal. That is, bonding can be confirmed by generation of a discontinuous portion on the side surface.

In addition, in a case where the conductor layers 106-1 and 201-1 are formed by a damascene method, each side surface has a tapered shape. As a result, the side wall of the conductor layer 106-1 and the side wall of the conductor layer 201-1 are not linear. Therefore, the shape of the cross section along the Z direction in the portion where the conductor layers 106-1 and 201-1 are bonded is a non-rectangular shape.

In addition, in a case where the conductor layers 106-1 and 201-1 are bonded, the first surface, the second surface, and the side surface of copper forming these are structured to be covered with the barrier metal. On the other hand, in a general wiring layer using copper, an insulator layer (silicon nitride, silicon carbide having nitrogen, or the like) having a function of preventing oxidation of copper is provided on the upper surface of copper, and no barrier metal is provided. Therefore, it is possible to distinguish the general wiring layer even when the positional bonding deviation does not occur.

### 1.2 Method for Manufacturing Semiconductor Memory Device

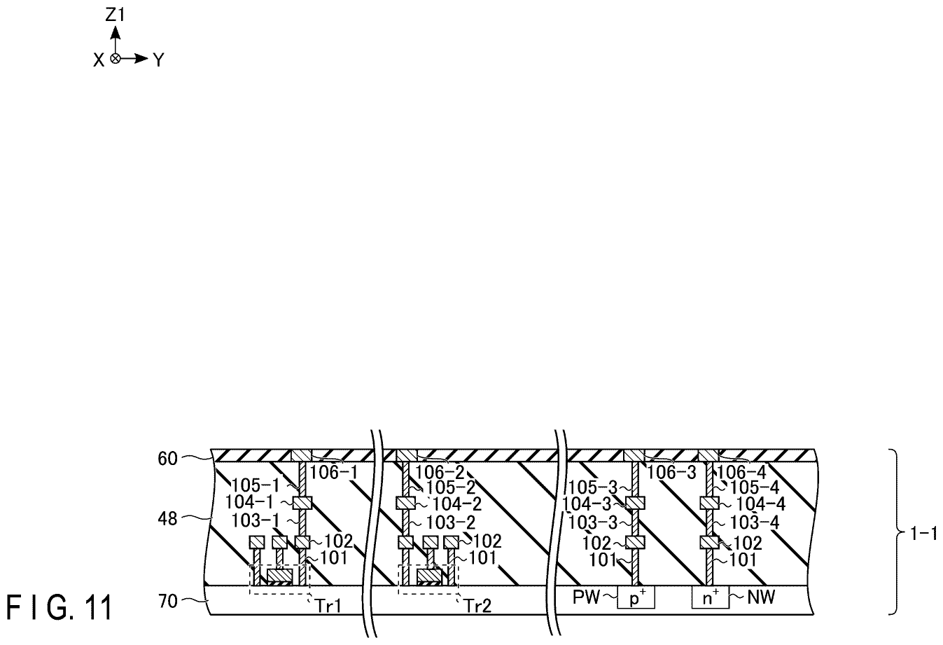

A method for manufacturing the semiconductor memory device 1 will be described with reference to FIGS. 11 to 21. FIGS. 11 to 21 are cross-sectional views for describing an example of a method for manufacturing the semiconductor memory device according to the first embodiment. The cross-sectional views illustrated in FIGS. 11 to 21 illustrate a region corresponding to FIG. 8.

First, as illustrated in FIG. 11, the transistors Tr1 and Tr2, the plurality of conductor layers 101 to 106, and the insulator layers 48 and 60 included in the peripheral circuit PERI are formed on the semiconductor substrate 70. That is, the circuit chip 1-1 is formed.

Next, a portion of the memory chip 1-2 is formed.

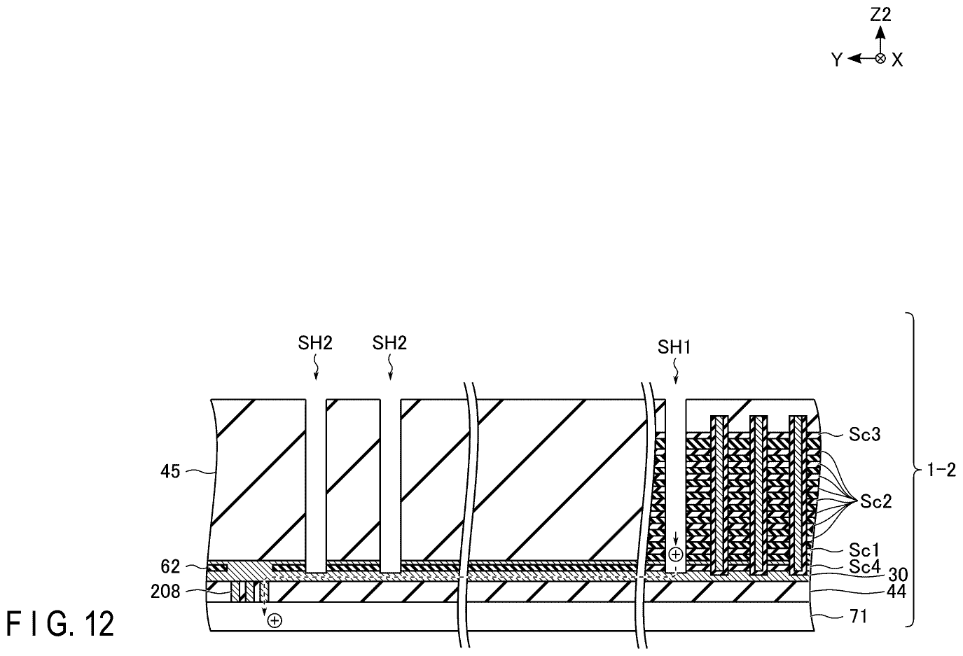

First, the plurality of conductor layers 208, a conductor layer 30 corresponding to the conductor layers 30A and 30B, sacrificial layers Sc1 and Sc3 corresponding to the conductor layers 31 and 33, a plurality of sacrificial layers Sc2 corresponding to the plurality of conductor layers 32, a sacrificial layer Sc4 provided in the same layer as the insulator layer 62 in the circuit region CR, insulator layers 40, 41, 43, 44, and 62, the plurality of insulator layers 42, the plurality of memory pillars MP, and the portion of the insulator layer 45 covering them are formed on the second surface of a semiconductor substrate 71 made of a P-type semiconductor doped with impurities. In the present process, a portion of the conductor layer 30 corresponding to the conductor layer 30A and a portion of the conductor layer 30 corresponding to the conductor layer 30B are electrically coupled to each other. Then, as illustrated in FIG. 12, a plurality of slits SH1 and SH2 is formed. More specifically, by anisotropic etching using a mask including openings corresponding the plurality of members SLT and the plurality of members W, a region where the plurality of members SLT is to be formed and a region where portions of the plurality of members W are to be formed are collectively removed. Thus, the plurality of slits SH1 and SH2 is formed. For example, the anisotropic etching is executed such that a portion corresponding to the conductor portion 30B-2 remains in each region overlapping the openings corresponding to the plurality of members W. The anisotropic etching in the present process is, for example, RIE. The mask is then removed.

Note that most of the large amount of positive charges generated in the process of forming holes corresponding to the memory pillars MP and the process of forming the plurality of slits SH1 and SH2 in the above process is released to the semiconductor substrate 71 via, for example, the conductor layers 30 and 208. Therefore, the occurrence of arcing around the conductor layers 30A and 30B is suppressed.

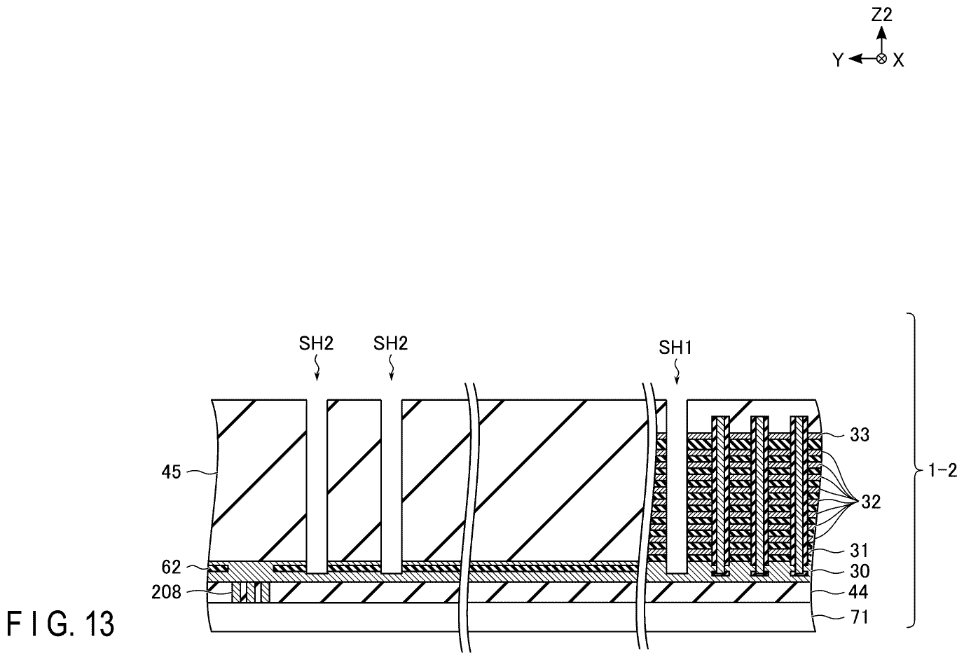

Then, as illustrated in FIG. 13, the sacrificial layers Sc1, Sc3, and Sc4 and the plurality of sacrificial layers Sc2 are respectively replaced with the conductor layers 31 and 33 and the conductor corresponding to a portion of the conductor layer 30A, and the plurality of conductor layers 32.

First, for example, the sacrificial layer Sc4 is selectively removed via the plurality of slits SH1 by wet etching with hot phosphoric acid. In this process, the wall surfaces in the plurality of slits SH1 above the sacrificial layer Sc4 are protected from wet etching by, for example, a protective film. Then, the portion of the stack film 52 of each memory pillar MP is removed through the space from which the sacrificial layer Sc4 has been removed. Then, the conductor is embedded in the space from which the sacrificial layer Sc4 has been removed. As a result, the portion of the conductor layer 30 corresponding to the conductor layer 30A is electrically coupled to the semiconductor film 51 of each memory pillar MP.

In addition, for example, the sacrificial layers Sc1 and Sc3 and the plurality of sacrificial layers Sc2 are selectively removed via the plurality of slits SH1 by wet etching with hot phosphoric acid. In this process, a portion of the conductor layer 30 corresponding to the conductor layer 30A formed as described above is protected from wet etching by, for example, a protective film. Then, the conductor is embedded in the space from which the sacrificial layers Sc1 and Sc3 and the plurality of sacrificial layers Sc2 are removed. As a result, the conductor layers 31 and 33 and the plurality of conductor layers 32 are formed.

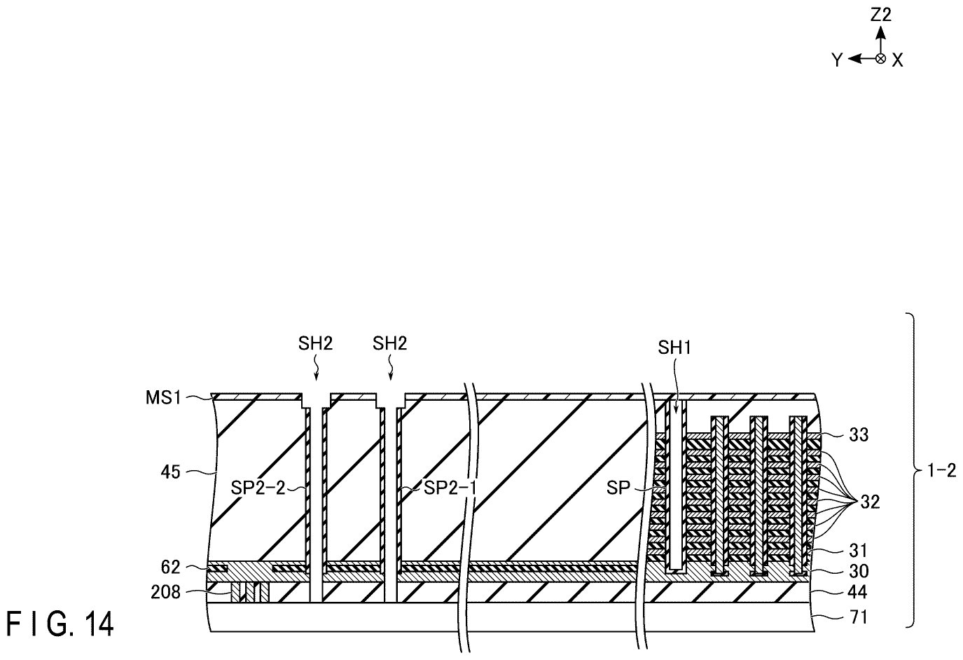

Then, as illustrated in FIG. 14, an insulating film SP corresponding to the spacer SP1, and the spacer SP2 are formed. More specifically, first, the insulating films SP corresponding to the spacers SP1 and SP2 are formed so as to cover the side surfaces and the first surfaces of the plurality of slits SH1 and SH2. Then, a mask MS1 in which regions corresponding to the plurality of slits SH2 are opened is formed. Then, a portion of the insulating film SP provided on the other side of the plurality of slits SH2 and a portion of the conductor layer 30 and the insulator layer 44 overlapping the portion in the Z direction are removed. As a result, the portion of the semiconductor substrate 71 is exposed on the other side of the plurality of slits SH2. In addition, the spacers SP2 are formed in the plurality of slits SH2.

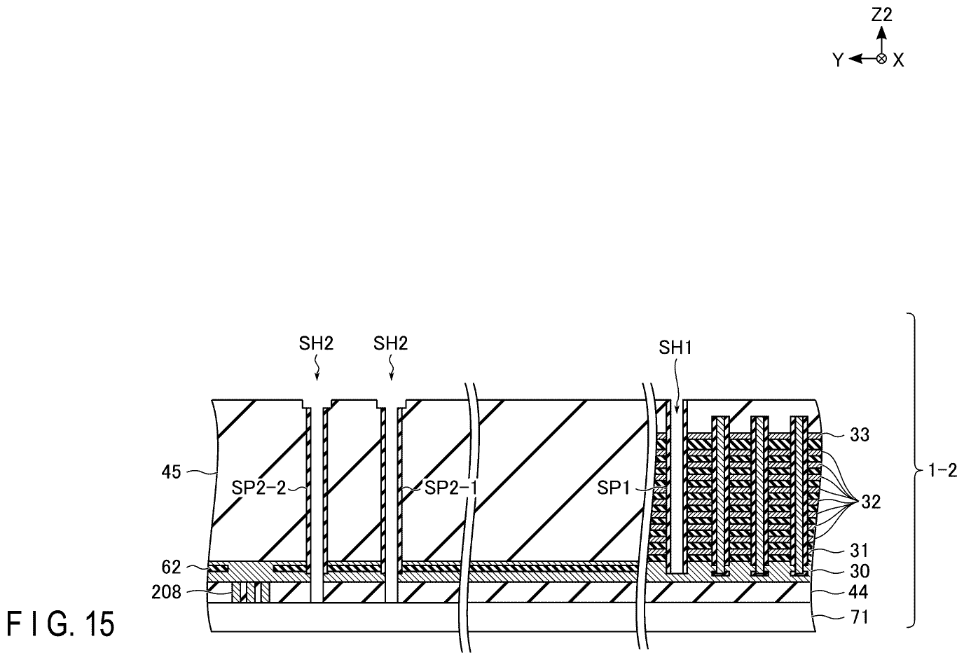

Then, after the mask MS1 is removed, as illustrated in FIG. 15, portions of the insulating films SP provided on the other side of the plurality of slits SH1 are removed. As a result, the portion of the conductor layer 30A is exposed on the other side of the plurality of slits SH1. In addition, the spacers SP1 are formed in the plurality of slits SH1.

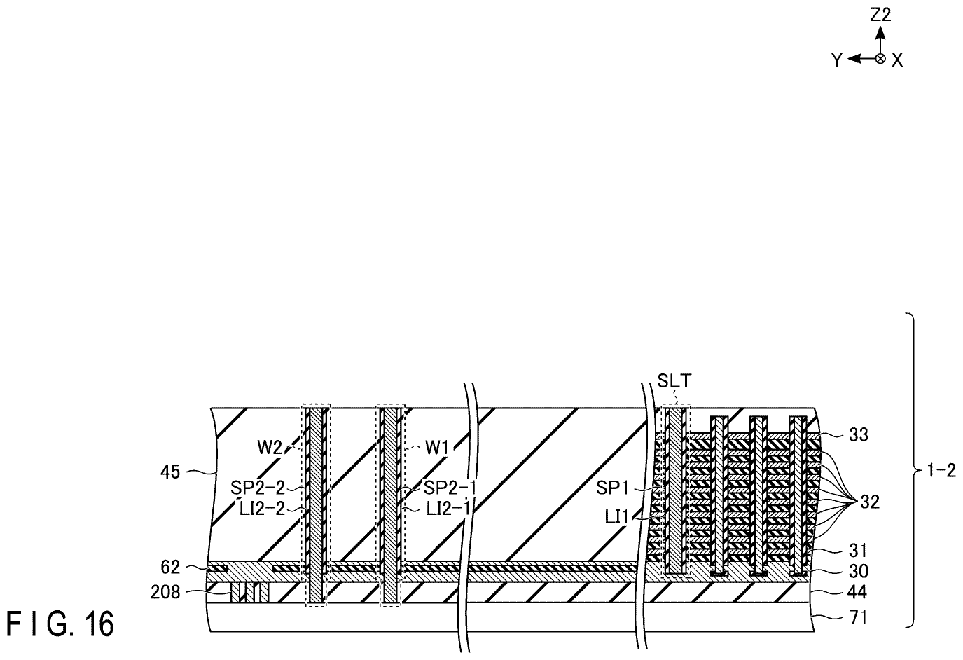

Next, as illustrated in FIG. 16, the plurality of members W and SLT is formed. More specifically, first, conductors corresponding to the plurality of contacts LI1 and LI2 are formed in the plurality of slits SH1 and SH2. Then, the conductor formed outside the plurality of slits SH1 and SH2 is removed and the second surface of the insulator layer 45 in which the conductors are embedded is set back by, for example, chemical mechanical polishing (CMP). Thus, the plurality of members W and SLT is formed.

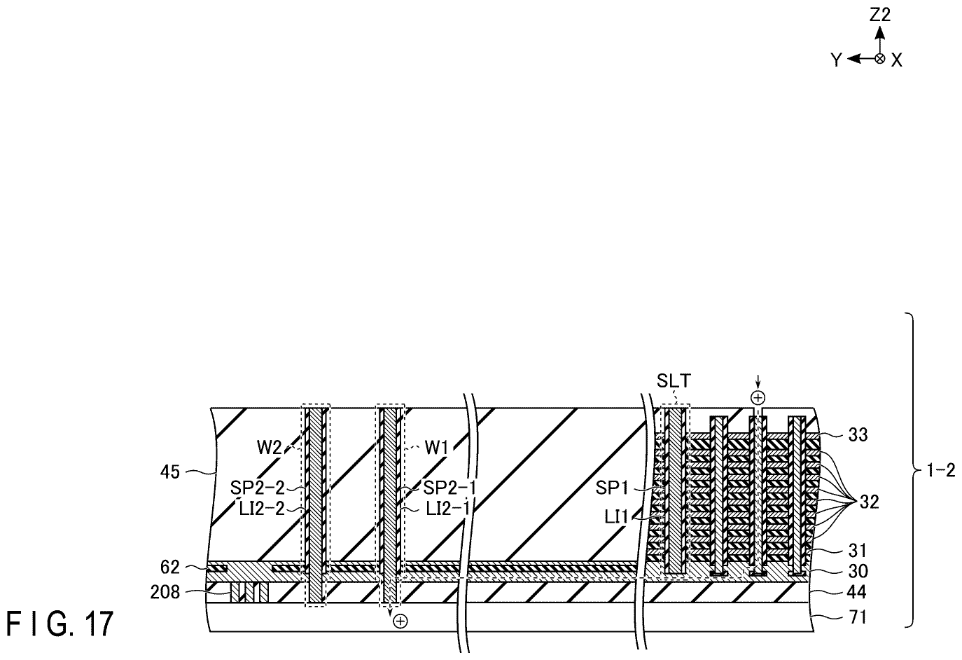

Next, for example, as illustrated in FIG. 17, regions of the insulator layer 45 on the memory pillars MP where the plurality of conductor layers 35 is to be formed are collectively removed by anisotropic etching using a mask including openings corresponding to the plurality of conductor layers 35. The anisotropic etching in the present process is, for example, RIE. In the present process, the positive charges generated by the anisotropic etching are released to the semiconductor substrate 71 via, for example, the semiconductor film 51 of the memory pillar MP, the conductor layer 30, and the plurality of members W. Thereafter, the conductor layer 35 is formed in the removed portion.

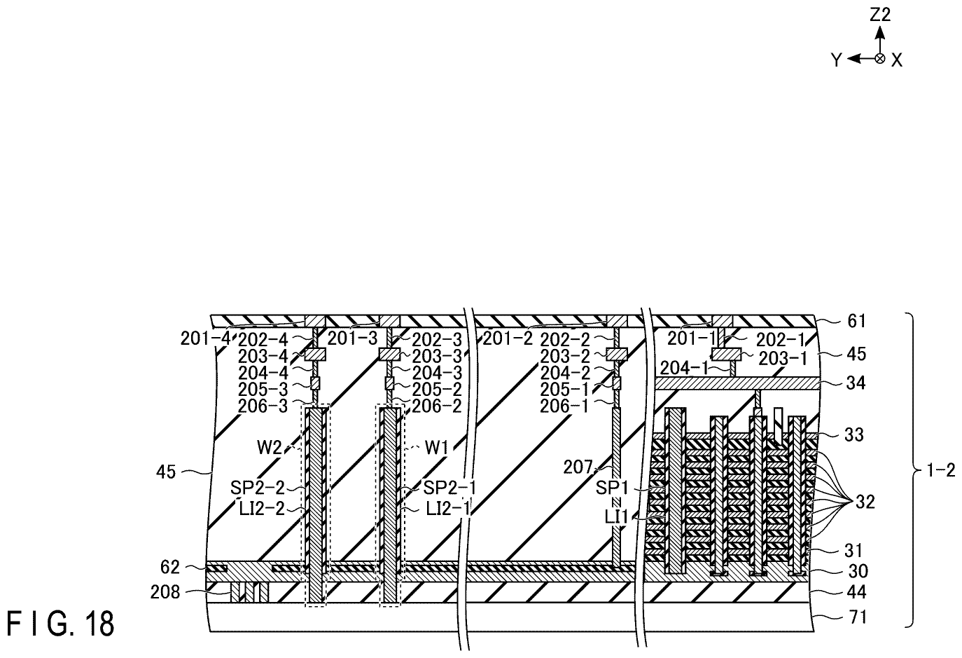

Then, as illustrated in FIG. 18, the conductor layer 207, the plurality of conductor layers 34, 36, and 201 to 206, a portion of the insulator layer 45 in which these are embedded, and the insulator layer 61 are formed. More specifically, the conductor layer 207 and the plurality of conductor layers 34, 36, and 201 to 206 are each formed by, for example, anisotropic etching using a mask, similarly to the plurality of conductor layers 35. In the process of forming the plurality of conductor layers 34, 36, and 201 to 206, the positive charges generated by the anisotropic etching are released to the semiconductor substrate 71 via, for example, the conductor layer 35, the semiconductor film 51 of the memory pillar MP, the conductor layer 30, and the plurality of members W.

By the above processes, a portion of the memory chip 1-2 is formed.

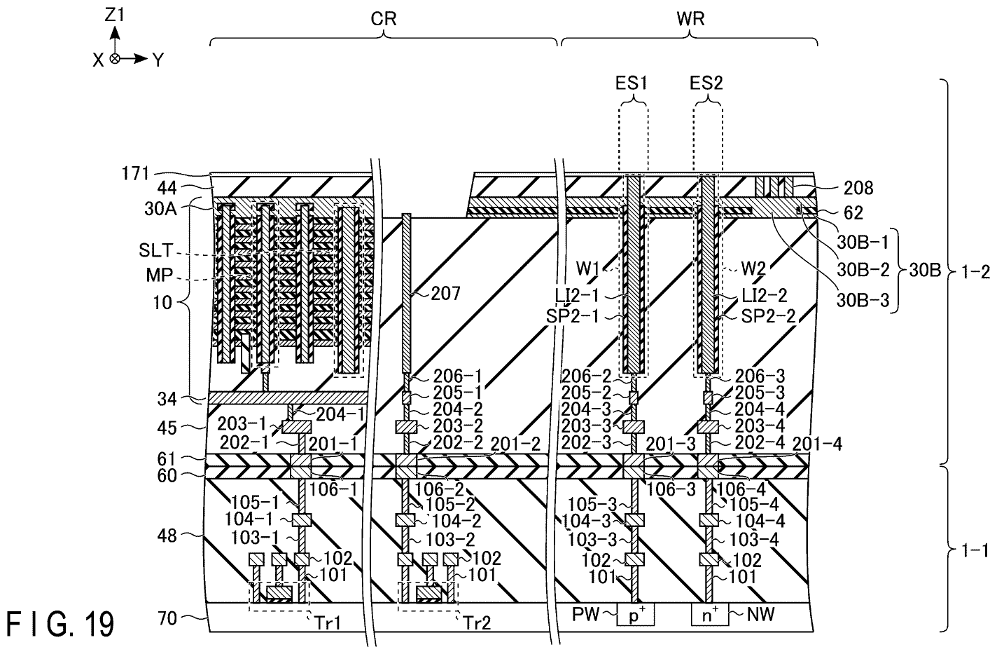

Then, the circuit chip 1-1 and the portion of the memory chip 1-2 are bonded by bonding processing. More specifically, the plurality of conductor layers 106 functioning as connection pads in the circuit chip 1-1 and the plurality of conductor layers 201 functioning as connection pads in the memory chip 1-2 are disposed to face each other. In addition, the connection pads facing each other are joined to each other by heat treatment. Thereafter, at least a portion of the semiconductor substrate 71 is removed, for example, by CMP. Then, a portion of the semiconductor substrate 71 that is not removed by CMP becomes the member 171. In addition, as illustrated in FIG. 19, for example, in a region surrounding the conductor layer 207, a portion of the conductor layer 30, a portion of the insulator layer 62, a portion of the insulator layer 44, and a portion of the member 171 are removed. As a result, the portion of the first surface of the insulator layer 45 is exposed. In addition, the conductor layer 30 is divided into the conductor layers 30A and 30B. As a result, the conductor layers 30A and 30B are electrically insulated from each other.

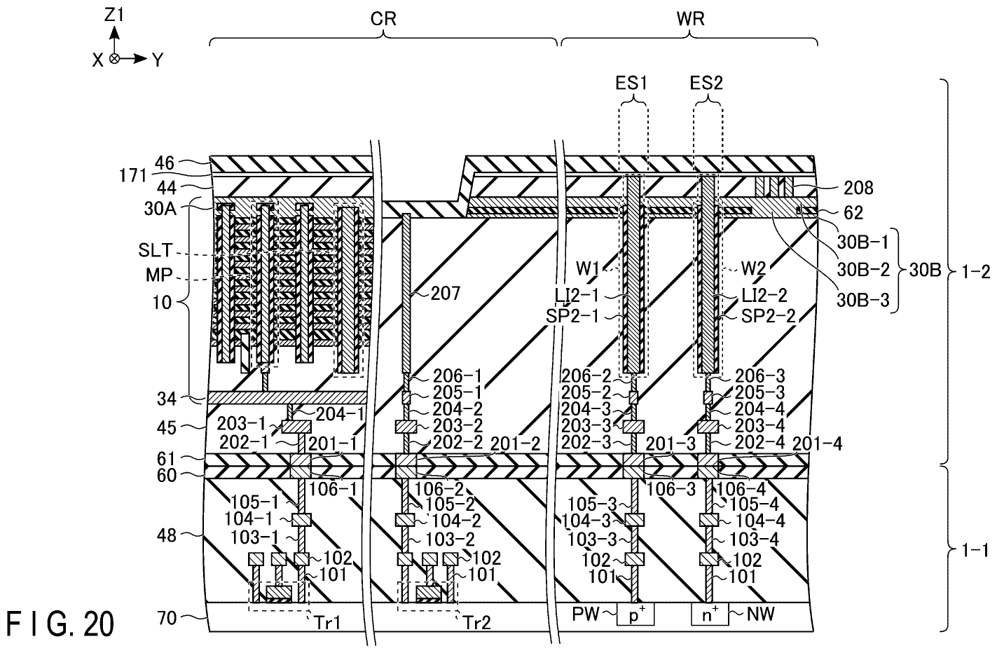

Next, as illustrated in FIG. 20, the insulator layer 46 is formed on, for example, the first surface of the member 171, the exposed portion of the first surface of the insulator layer 45, and the first surface of the conductor layer 207.

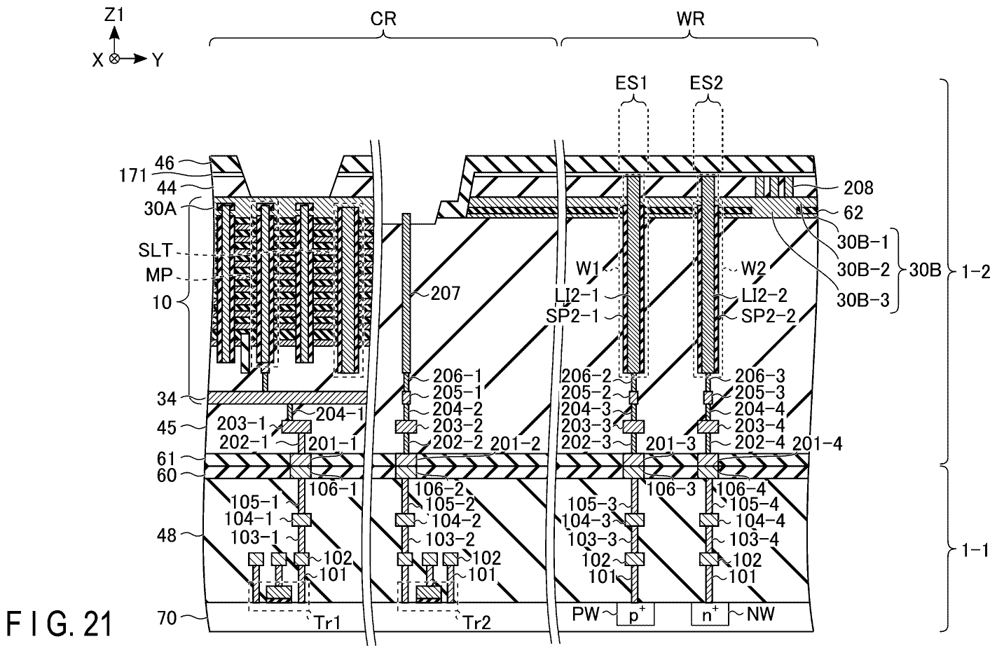

Then, as illustrated in FIG. 21, a portion of the insulator layer 46 where the conductor layer 37 is coupled to each of the conductor layer 30A and the conductor layer 207 is removed by, for example, processing using lithography and etching.

Then, the conductor layer 37 and the insulator layer 47 are formed.

The semiconductor memory device 1 is formed by the above-described manufacturing process.

Note that the manufacturing processes described above are merely examples, and other pieces of processing may be inserted between the manufacturing processes, or the order of the manufacturing processes may be changed. For example, since the circuit chip 1-1 and the portion of the memory chip 1-2 are formed using the semiconductor substrates 70 and 71 different from each other, the process of forming the circuit chip 1-1 illustrated in FIG. 11 and the process of forming the portion of the memory chip 1-2 illustrated in FIGS. 12 to 18 can be performed in parallel.

### 1.3 Effect

According to the embodiment, it is possible to suppress a decrease in yield of the semiconductor memory device 1. Hereinafter, effects of the embodiment will be described.

According to the embodiment, the semiconductor memory device 1 includes the semiconductor substrate 70, the memory cell array 10, the members W, and the conductor portion 30B-2. The semiconductor substrate 70 has the circuit region CR and the wall region WR provided so as to surround the circuit region CR. The memory cell array 10 is provided in the circuit region CR. The conductor portion 30B-2 is included in the same layer as the source line SL, and the first surface has the first height substantially equivalent to the first surface of the source line SL. The conductor portion 30B-2 is electrically insulated from the source line SL. The members W include the contacts LI2 and the spacers SP2. The contact LI2 is provided so as to surround the plurality of word lines WL while being separated from the plurality of word lines WL. The contact LI2 extends in the Z direction at least in a range substantially equivalent to the plurality of word lines WL. In addition, the contact LI2 reaches the other side with respect to the first height of the first surface of the conductor portion 30B-2 in the Z direction. The contact LI2 is integrally provided along the Z direction. The spacer SP2 covers the side surface of the contact LI2 from the second height approximately equivalent to the height of the second surface of the contact LI2 to the third height on one side with respect to the first surface of the contact LI2. With the above configuration, for example, in the memory chip 1-2, it is possible to suppress the occurrence of defects due to melting of conductors such as electrodes provided on one side with respect to the conductor layer 35. Accordingly, it is possible to suppress a decrease in yield of the semiconductor memory device 1.

To supplement, in the process of manufacturing the semiconductor memory device, in a case where holes for forming the contact and the wiring are formed by anisotropic etching, positive charges may be accumulated at the bottoms of the holes. As a result, the conductors formed near the holes may be positively charged. In such a case, the conductors may be melted. For example, in the configuration in which the circuit chip and the memory chip are bonded to each other, in a case where the sealing portion included in the memory chip is provided at a position lower than the first surface of the source line, the contact and the wiring on one side with respect to the memory pillar may be positively charged. That is, in a case where the portion of the memory chip is formed before the circuit chip and the memory chip are bonded to each other, positive charges generated in the process of forming the contact and the wiring may not be released to the semiconductor substrate by the antistatic member. Therefore, in the above case, the contact and the wiring on one side with respect to the memory pillar may be melted.

According to the first embodiment, in a case where the portion of the memory chip 1-2 is formed before the circuit chip 1-1 and the memory chip 1-2 are bonded to each other, positive charges generated in the process of forming the contact and the wiring on one side with respect to the memory pillar MP are released to the semiconductor substrate 71 via the contact LI2 of the member Was illustrated in FIG. 17. As a result, the contact and the wiring on one side with respect to the memory pillar MP are prevented from being positively charged. Accordingly, it is possible to suppress the occurrence of defects in the semiconductor memory device 1.

### 2 Modification of First Embodiment

The above-described first embodiment can be variously modified. Hereinafter, a semiconductor memory device according to a modification of the first embodiment will be described.

### 2.1 First Modification of First Embodiment

In the first embodiment described above, the case where the contact LI2 of the member W penetrates the insulator layer 44 over the entire region where each sealing portion ES is provided has been described, but it is not limited thereto. In each sealing portion ES, the contact LI2 of the member W may include a portion that does not penetrate the insulator layer 44. Hereinafter, a configuration and a manufacturing method of the semiconductor memory device 1 according to the first modification of the first embodiment will be described in terms of differences from the configuration and the manufacturing method of the semiconductor memory device according to the first embodiment.

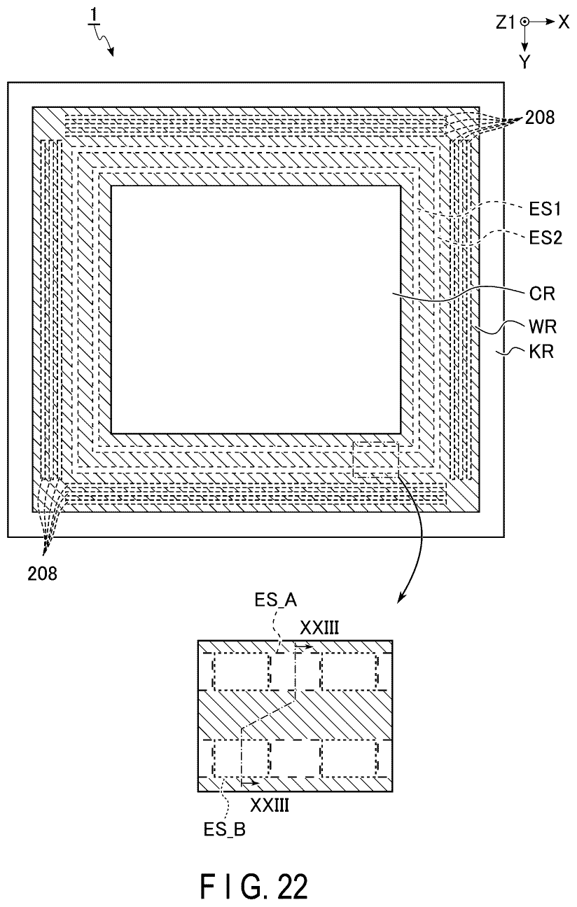

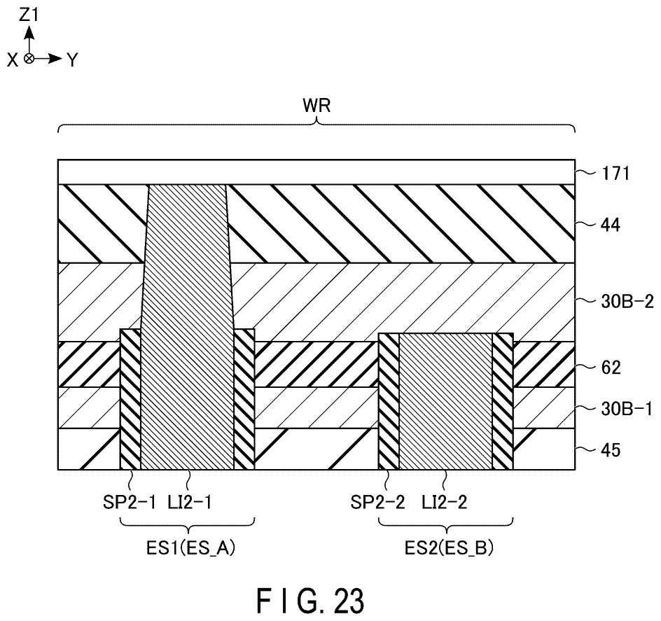

A configuration of the semiconductor memory device 1 according to the first modification of the first embodiment will be described with reference to FIGS. 22 and 23. FIG. 22 is a plan view illustrating an example of a planar layout of the semiconductor memory device according to the first modification of the first embodiment. FIG. 23 is a cross-sectional view taken along line XXIII-XXIII of FIG. 22, illustrating an example of a cross-sectional structure of a sealing portion of the semiconductor memory device according to the first modification of the first embodiment.

As illustrated in FIG. 22, in the semiconductor memory device 1 according to the first modification of the first embodiment, each sealing portion ES is divided into a plurality of regions ES_A and ES_B. In addition, in each sealing portion ES, for example, as the plurality of regions ES_A and ES_B, regions ES_A and ES_B are alternately disposed. That is, the plurality of regions ES_A and ES_B is intermittently provided so as to surround the circuit region CR.

FIG. 23 illustrates a structure on the other side of the sealing portion ES1 in the region ES_A and a structure on the other side of the sealing portion ES2 in the region ES_B.

The structure of the sealing portion ES in the region ES_A is the same as the structure of the sealing portion ES in the first embodiment. That is, the contact LI2 in the region ES_A reaches the other side with respect to the first height of the first surface of the conductor portion 30B-2 in the Z direction.

In the region ES_B, the structure of the spacer SP2 is the same as the structure of the spacer SP2 in the region ES_A. The height of the first surface of the contact LI2 in the region ES_B is lower than the second surface of the insulator layer 44. That is, the contact LI2 in the region ES_B is provided exclusively on one side in the Z direction with respect to the first height of the first surface of the conductor portion 30B-2. The height of the first surface of the contact LI2 in the region ES_B is, for example, the same as the height of the first surface of the spacer SP2.

With the above configuration, the semiconductor memory device 1 includes a portion of the contact LI2 penetrating the insulator layer 44 in the region ES_A and a portion of the contact LI2 having the first surface lower than the second surface of the insulator layer 44 in the region ES_B.

Note that the method for manufacturing the semiconductor memory device 1 according to the first modification of the first embodiment is substantially the same in the process corresponding to FIG. 14 of the first embodiment except that the shape of the mask MS1 is different. In the first modification of the first embodiment, for example, while leaving the portion of the insulating film SP provided on the other side of the portion corresponding to the region ES_B within the plurality of slits SH2, the portion of the insulating film SP provided on the other side of the portion corresponding to the region ES_A within the plurality of slits SH2 and the portions of the conductor layer 30B and the insulator layer 44 overlapping the portion in the Z direction are removed. In addition, in the process corresponding to FIG. 15 of the first embodiment, in addition to removing the portion of the insulating film SP provided on the other side of the plurality of slits SH1, for example, the portion of the insulating film SP provided on the other side of the portion corresponding to the region ES_B within the plurality of slits SH2 is removed.

The first modification of the first embodiment also achieves effects equivalent to those of the first embodiment.

### 2.2 Second Modification of First Embodiment

In the first embodiment described above, the case where the contact LI2 of the member W is surrounded by the insulator layer 44 and the member 171 at one end on the other side of each sealing portion ES has been described, but it is not limited thereto. At one end on the other side of each sealing portion ES, the contact LI2 of the member W may be configured to be in contact with the conductor layer, for example. Hereinafter, a configuration and a manufacturing method of the semiconductor memory device 1 according to the second modification of the first embodiment will be described in terms of differences from the configuration and the manufacturing method of the semiconductor memory device according to the first embodiment.

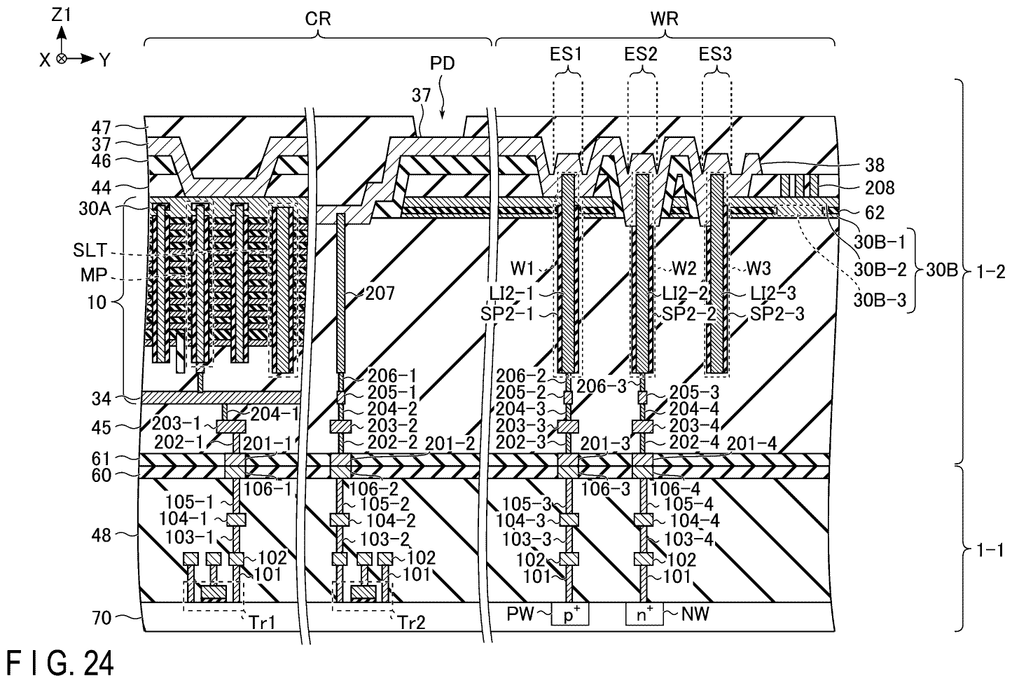

A configuration of the semiconductor memory device 1 according to the second modification of the first embodiment will be described with reference to FIG. 24. FIG. 24 is a cross-sectional view illustrating an example of a cross-sectional structure in a circuit region and a wall region of a semiconductor memory device according to the second modification of the first embodiment. In FIG. 24, in the sealing portion ES, three members W in which the structure of the spacer SP2 and the structure of the outer periphery of the contact LI2 are different from those of the semiconductor memory device according to the first embodiment are illustrated. Note that, in the second modification of the first embodiment, an example of the case where the member 171 is not provided by fully removing the semiconductor substrate 71 in the manufacturing process is described.

In the second modification of the first embodiment, the semiconductor memory device 1 further includes a sealing portion ES3. That is, the semiconductor memory device 1 includes three sealing portions ES in the wall region WR. The sealing portion ES3 includes a member W3. The member W3 includes a contact LI2-3 and a spacer SP2-3 as the contact LI2 and the spacer SP2, respectively. In addition, the semiconductor memory device 1 further includes a conductor layer 38. Note that the contact LI2-3 is electrically coupled to the semiconductor substrate 70 in a region, which is not illustrated, for example.

The conductor layer 38 couples, for example, the contacts LI2-1, LI2-2, and LI2-3 included in the members W1, W2, and W3, respectively.

The contact LI2-1 of the member W1 is surrounded by the conductor layer 38 at the same height as the insulator layer 44. Note that, in the Z direction, the structure of the member W1 on one side with respect to the insulator layer 44 is the same as the structure of the member W1 on one side with respect to the insulator layer 44 in the first embodiment. In the member W1, a portion on one side in the Z direction with respect to the second surface of the insulator layer 44 is surrounded by the conductor layer 30B and the insulator layer 62.

A portion on the other side of the member W2 is surrounded by the conductor layer 38 over the same height as the insulator layers 44 and 62 and the same height as the conductor layer 30B. For example, within the side surface of the contact LI2-2, a side surface portion on the other side that is not covered with the spacer SP2-2 forming the end on the other side in the vicinity of the height position of the first surface of the insulator layer 45 in the Z direction is surrounded by the conductor layer 38. In the portion surrounding the member W2, the conductor layer 38 may reach one side in the Z direction with respect to the second surface of the conductor layer 30B. For example, in the portion surrounding the member W2, the conductor layer 38 may be provided such that the second surface of the conductor layer 38 has the same height as the second surface of the conductor layer 37 around the conductor layer 207. The spacer SP2-2 is provided from approximately the second height of the second surface of the contact LI2-2 to the height of the second surface of the conductor layer 38 in the portion surrounding the member W2 on the side surface of the contact LI2-2.

The portion on the other side of the member W3 is in contact with, for example, the conductor layer 38, the conductor layer 30B, and the insulator layer 62 in a part of the outer periphery thereof, similarly to the member W1. In addition, the portion on the other side of the member W3 is in contact with the conductor layer 38 over the same height as the insulator layers 44 and 62 and the same height as the conductor layer 30B, for example, in the other portion of the outer periphery thereof, similarly to the member W2. In the portion surrounding the member W3, the second surface of the conductor layer 38 may have different heights. More specifically, for example, in the portion surrounding the member W3, the conductor layer 38 is provided such that at least a first portion of the second surface of the conductor layer 38 has the same height as the second surface of the conductor layer 37 around the conductor layer 207. In addition, for example, in the portion surrounding the member W3, the conductor layer 38 is provided such that a second portion different from the first portion of the second surface of the conductor layer 38 has the same height as the second surface of the conductor layer 38 in the portion surrounding the member W1. In the portion overlapping the first portion in the Z direction, the spacer SP2-3 is provided from approximately the second height of the second surface of the contact LI2-3 to the height of the second surface of the conductor layer 38 on the side surface of the contact LI2-3. In addition, in the portion overlapping the second portion in the Z direction, the spacer SP2-3 is provided similarly to the spacer SP2-1.

Note that the method for manufacturing the semiconductor memory device 1 according to the second modification of the first embodiment is substantially the same except that the portions removed in the processes corresponding to FIGS. 19 to 21 of the first embodiment are different and the conductor layer 38 is formed. Note that in the processes corresponding to FIGS. 19 and 21 of the first embodiment, the structure of the spacer SP2-2 and the spacer SP2-3 as described above is formed by removing the portions on the other side of the spacer SP2-2 of the member W2 and the spacer SP2-3 of the member W3.

The second modification of the first embodiment also achieves effects equivalent to those of the first embodiment. Note that, in the second modification of the first embodiment, the case where the members W1, W2, and W3 having different structures are formed as the plurality of sealing portions ES has been described, but it is not limited thereto. That is, any one or two of the three members W1, W2, and W3 illustrated in FIG. 24 may be formed for the plurality of sealing portions ES, or the members W in the first embodiment and the second modification of the first embodiment may be formed in combination.

### 2.3 Third Modification of First Embodiment

In the third modification of the first embodiment, the member W is manufactured by a process different from that of the first embodiment described above. Hereinafter, a configuration and a manufacturing method of the semiconductor memory device 1 according to the third modification of the first embodiment will be described in terms of differences from the configuration and the manufacturing method of the semiconductor memory device according to the first embodiment.

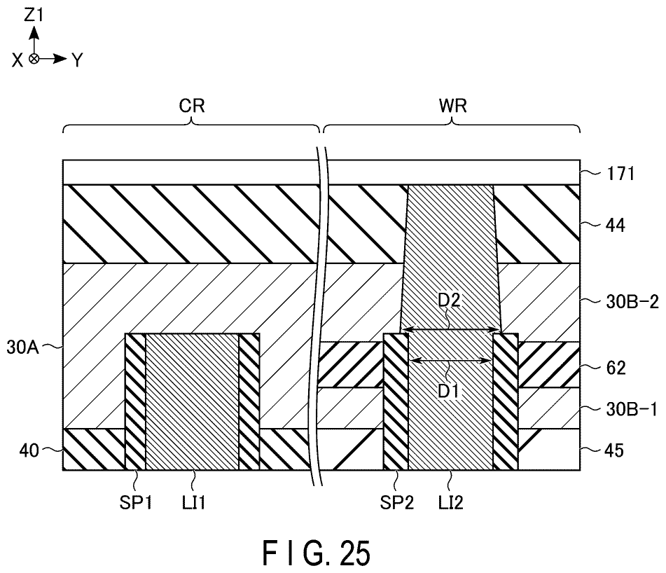

A configuration of the semiconductor memory device 1 according to the third modification of the first embodiment will be described with reference to FIG. 25. FIG. 25 is a cross-sectional view illustrating an example of a cross-sectional structure of a sealing portion of the semiconductor memory device according to the third modification of the first embodiment.

The portion of the contact LI2 provided on the other side with respect to the spacer SP2 of each sealing portion ES may have a portion wider than a width D1 between the portion on one side of the spacer SP2 in the Y direction and the portion on the other side in the Y direction in a YZ cross section. A width D2 of the contact LI2 on the most one side in the Z direction within the portion of the contact LI2 provided on the other side with respect to the spacer SP2 of each sealing portion ES is, for example, wider than the width D1. In addition, although not illustrated, each sealing portion ES can have the same structure also in an XZ cross section.

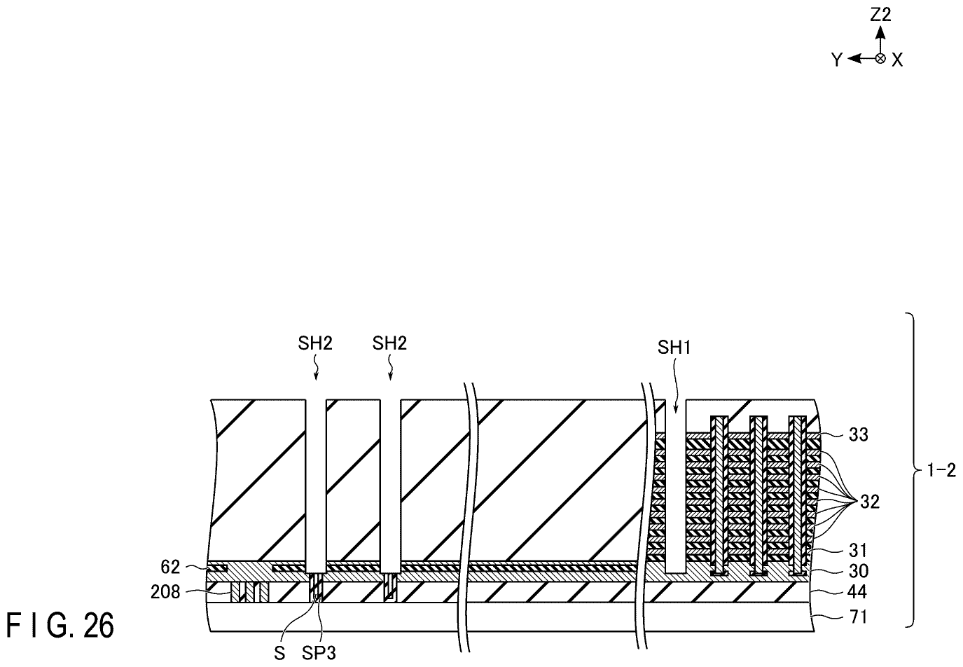

A method for manufacturing the semiconductor memory device 1 according to the third modification of the first embodiment will be described with reference to FIGS. 26, 27, 28, and 29. FIGS. 26 to 29 are cross-sectional views for describing an example of a method for manufacturing the semiconductor memory device according to the third modification of the first embodiment.

In the third modification of the first embodiment, the same processes as the processes described with reference to FIGS. 12 and 13 are executed.

In addition, for example, portions of the conductor layer 30B and the insulator layer 44 overlapping the plurality of slits SH2 in the Z direction are removed by anisotropic etching using a mask including openings corresponding to the plurality of slits SH2. The anisotropic etching in the present process is, for example, RIE. The mask is then removed.

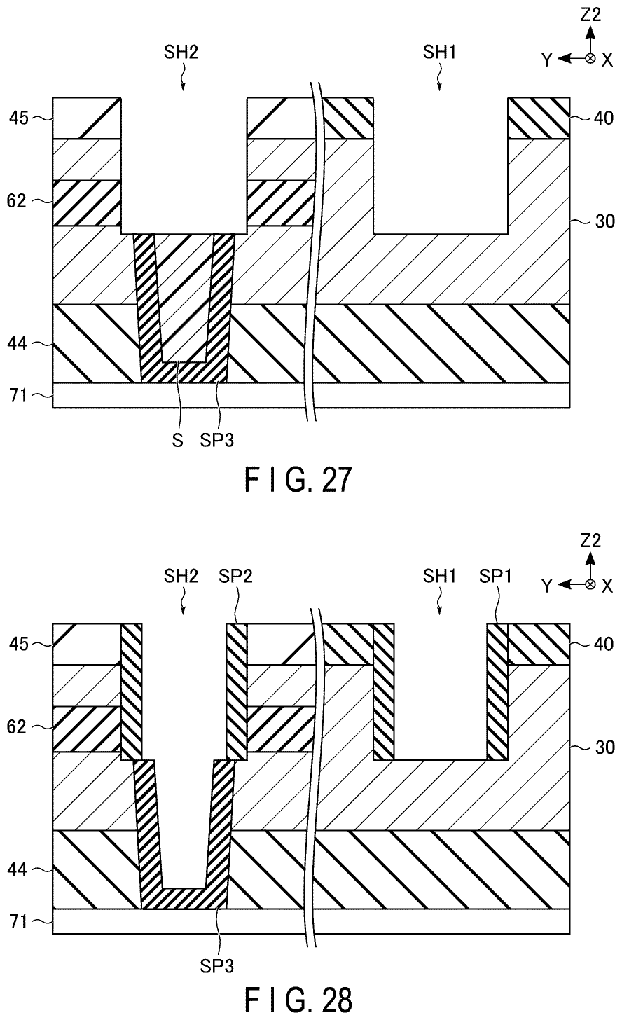

Then, as illustrated in FIGS. 26 and 27, for example, spacers SP3 and sacrificial materials S are formed in the portions on the other side in the plurality of slits SH2. The spacer SP3 and the sacrificial material S are formed at the same height as the conductor portion 30B-2 and the insulator layer 44, for example.

Then, as illustrated in FIG. 28, after the spacers SP1 and SP2 are formed, the sacrificial material S in each slit SH2 is removed.

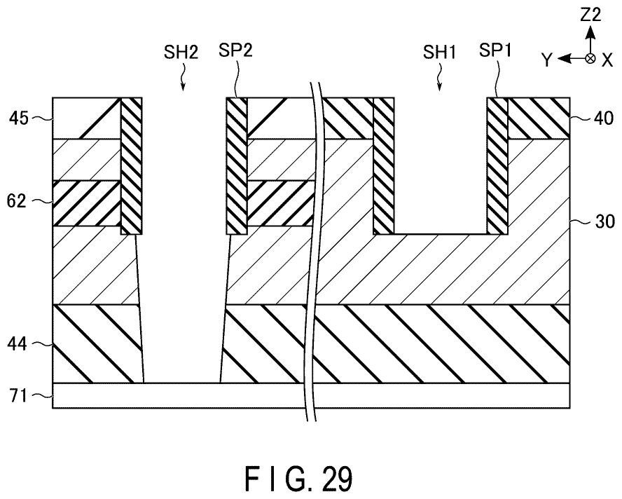

In addition, as illustrated in FIG. 29, the spacer SP3 in each slit SH2 is removed. The spacer SP3 is removed by, for example, chemical dry etching (CDE).

Other processes are the same as those in the method for manufacturing the semiconductor memory device 1 according to the first embodiment.

The semiconductor memory device 1 is formed by the above-described manufacturing process.

The third modification of the first embodiment also achieves effects equivalent to those of the first embodiment.

### 2.4 Fourth Modification of First Embodiment

In the first embodiment and the first to third modifications of the first embodiment, the case where the member W does not include the spacer in the same layer as the insulator layer 44 has been described, but it is not limited thereto. The member W may include a spacer in the same layer as the insulator layer 44. Hereinafter, a configuration and a manufacturing method of the semiconductor memory device 1 according to the fourth modification of the first embodiment will be described in terms of differences from the configuration and the manufacturing method of the semiconductor memory device according to the first embodiment.

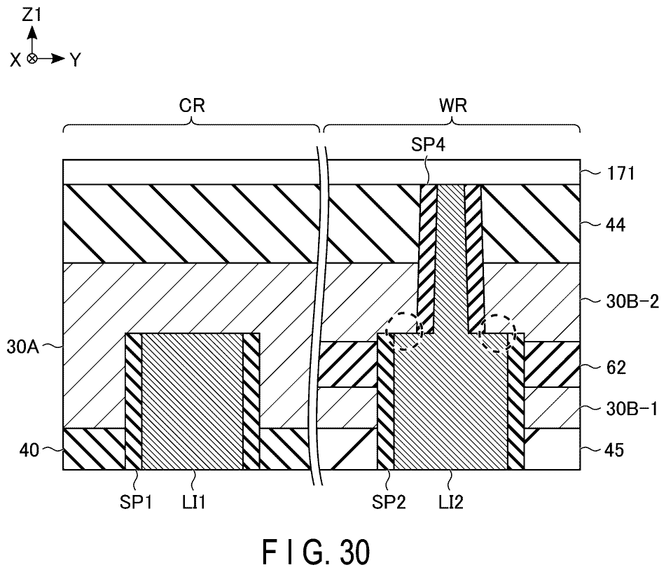

A configuration of the semiconductor memory device 1 according to the fourth modification of the first embodiment will be described with reference to FIG. 30. FIG. 30 is a cross-sectional view illustrating an example of a cross-sectional structure of a sealing portion of the semiconductor memory device according to the fourth modification of the first embodiment. In FIG. 30, the cross-sectional structure of the portion of the contact LI2 and the spacer SP2 in the member W is illustrated together with the cross-sectional structure of the portion of the contact LI1 and the spacer SP1 in the member SLT.

The semiconductor memory device 1 according to the fourth modification of the first embodiment further includes a spacer SP4. The spacer SP4 is an insulator provided on a side surface of the contact LI2 on the other side of the spacer SP2 provided in the range excluding the portion on the other side of the contact LI2 within the side surface of the contact LI2 of each sealing portion ES. The third height of the end on the other side of the spacer SP2 is equivalent to a fourth height of the first surface of the insulator layer 62 or is located on the other side with respect to the fourth height. In addition, when viewed in the Z direction, an outer diameter of the spacer SP4 is smaller than an inner diameter of the spacer SP2, for example. As a result, as indicated by dotted lines in FIG. 30, the contact LI2 is coupled to the conductor portion 30B-2 between the spacer SP2 and the spacer SP4 along the Y direction. In addition, although not illustrated, the contact LI2 is also coupled to the conductor portion 30B-2 between the spacer SP2 and the spacer SP4 along the X direction.

Note that the third height of the first surface of the end on the other side of the spacer SP2 is substantially the same as the height of the second surface of the end on the one side of the spacer SP4, for example. In this case, even when there is a portion where the spacer SP2 and the spacer SP4 are in contact with each other due to positional deviation or the like, the spacer SP2 and the spacer SP4 can be distinguished from each other by the end on the other side of the spacer SP2, for example, since there is a portion where the contact LI2 and the conductor portion 30B-2 are coupled as described above.

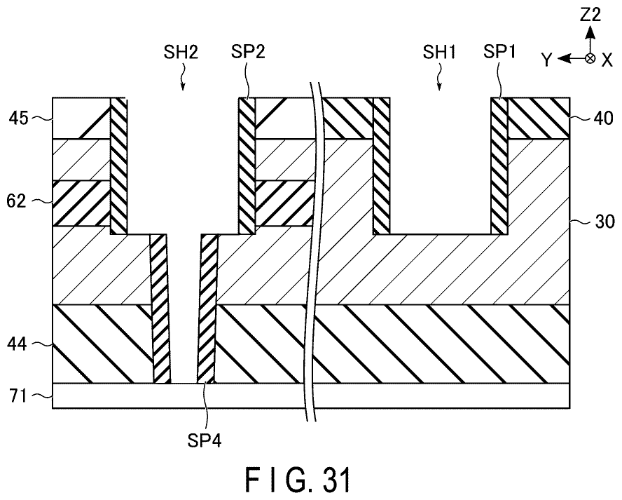

A method for manufacturing the semiconductor memory device 1 according to the fourth modification of the first embodiment will be described with reference to FIG. 31. FIG. 31 is a cross-sectional view for describing an example of a method for manufacturing the semiconductor memory device according to the fourth modification of the first embodiment.

In the fourth modification of the first embodiment, the same processes as the processes described with reference to FIGS. 26 to 28 of the third modification of the first embodiment are executed. Note that, in the fourth modification of the first embodiment, an insulator film corresponding to the spacer SP4 is formed instead of the spacer SP3. In addition, in the fourth modification of the first embodiment, the spacers SP2 and SP4 are formed so that the contact LI2 and the conductor portion 30B-2 are coupled between the spacer SP2 and the spacer SP4.

In addition, as illustrated in FIG. 31, the portion of the insulator film corresponding to the spacer SP4 in contact with the semiconductor substrate 71 is removed by anisotropic etching using a mask including openings corresponding to the plurality of slits SH2. The anisotropic etching in the present process is, for example, RIE. The mask is then removed.

Other processes are the same as those in the method for manufacturing the semiconductor memory device 1 according to the third modification of the first embodiment.

The semiconductor memory device 1 is formed by the above-described manufacturing process.

The fourth modification of the first embodiment also achieves effects equivalent to those of the first embodiment.

### 3 Second Embodiment

Hereinafter, a semiconductor memory device according to a second embodiment will be described. The semiconductor memory device according to the second embodiment is configured such that a contact LI1 of a member SLT in a memory cell array 10 is in contact with a semiconductor substrate 71 of a memory chip 1-2 instead of a contact LI2 of a member W being in contact with the semiconductor substrate 71 of the memory chip 1-2 in a manufacturing process. Hereinafter, a configuration and a manufacturing method of the semiconductor memory device according to the second embodiment will be described mainly in terms of differences from the configuration and the manufacturing method of the semiconductor memory device according to the first embodiment.

### 3.1 Configuration

Hereinafter, a configuration of the semiconductor memory device 1 according to the second embodiment will be described. Hereinafter, a cross-sectional structure of the memory cell array 10 and an overall cross-sectional structure of the semiconductor memory device 1 will be described.

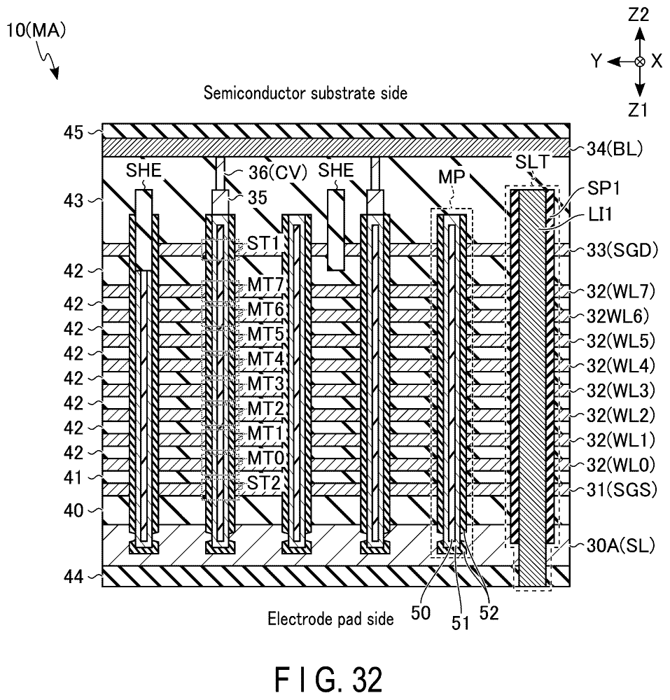

First, a cross-sectional structure in a memory region MA of the memory cell array 10 will be described with reference to FIG. 32. FIG. 32 is a cross-sectional view illustrating an example of a cross-sectional structure of the memory cell array of the semiconductor memory device according to the second embodiment.

The contact LI1 of the semiconductor memory device 1 according to the second embodiment penetrates a conductor layer 30A and an insulator layer 44. For example, a spacer SP1 covers a side surface of the contact LI1 from a height of the second surface of the contact LI1 to a height on one side with respect to the second surface of the insulator layer 44. As a result, the contact LI1 is coupled to the conductor layer 30A.

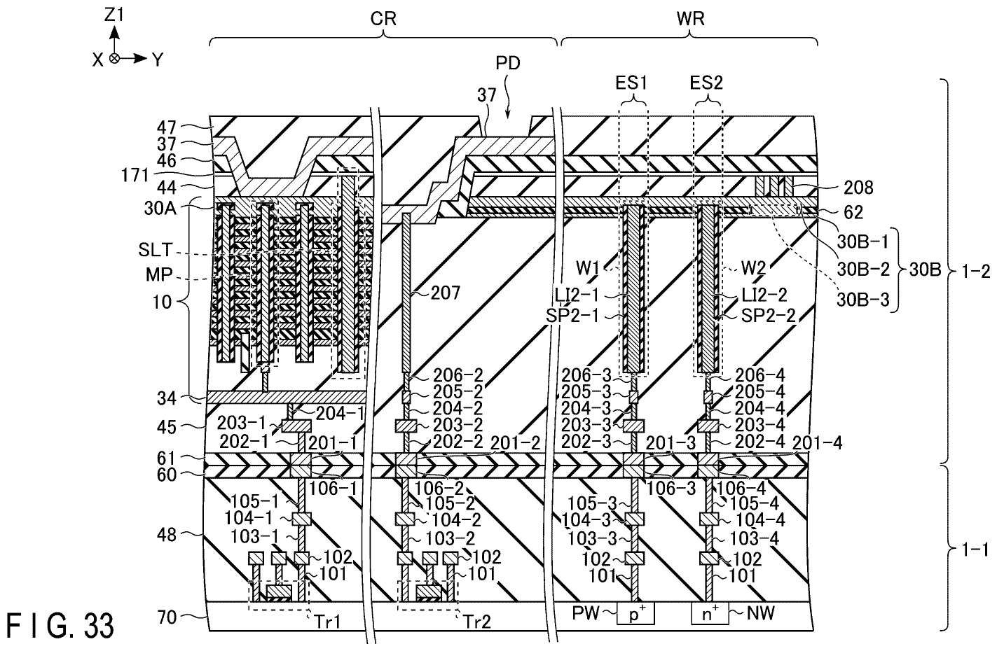

Next, an overall cross-sectional structure of the semiconductor memory device 1 will be described with reference to FIG. 33. FIG. 33 is a cross-sectional view illustrating an example of a cross-sectional structure in a circuit region and a wall region of the semiconductor memory device according to the second embodiment. FIG. 33 illustrates a cross-sectional structure of a portion of the semiconductor memory device 1 corresponding to FIG. 8.

In the memory chip 1-2, as described above, the contact LI1 penetrates the conductor layer 30A and the insulator layer 44. The first surface of the contact LI1 is provided to be flush with the first surface of the insulator layer 44. As a result, as illustrated in FIG. 33, the first surface of the contact LI1 is in contact with a member 171. Note that in a case where the semiconductor memory device 1 does not include the member 171, the first surface of the contact LI1 is in contact with, for example, the second surface of an insulator layer 46.

### 3.2 Method for Manufacturing Semiconductor Memory Device

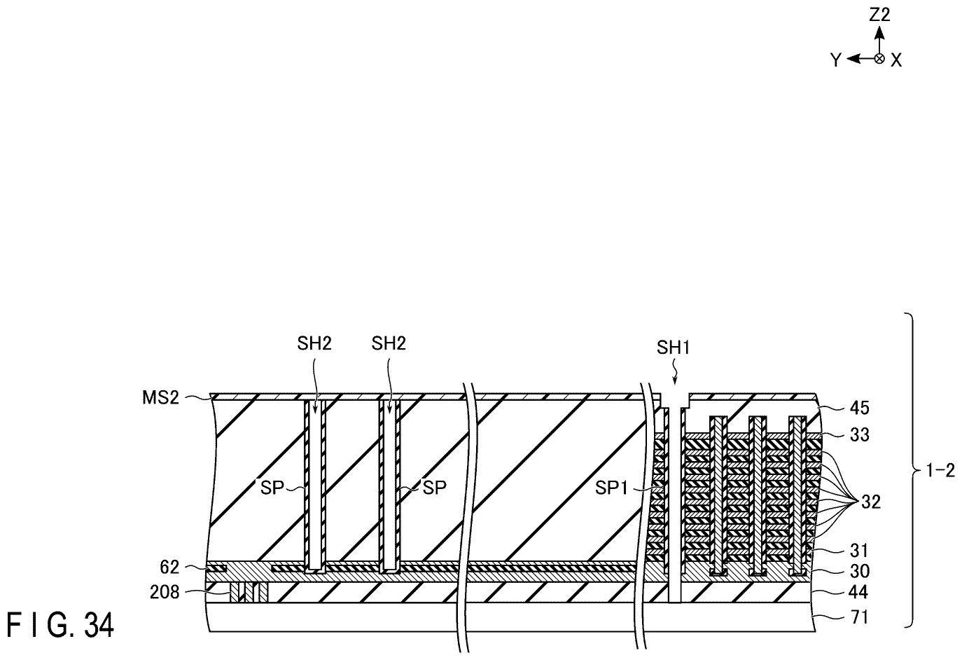

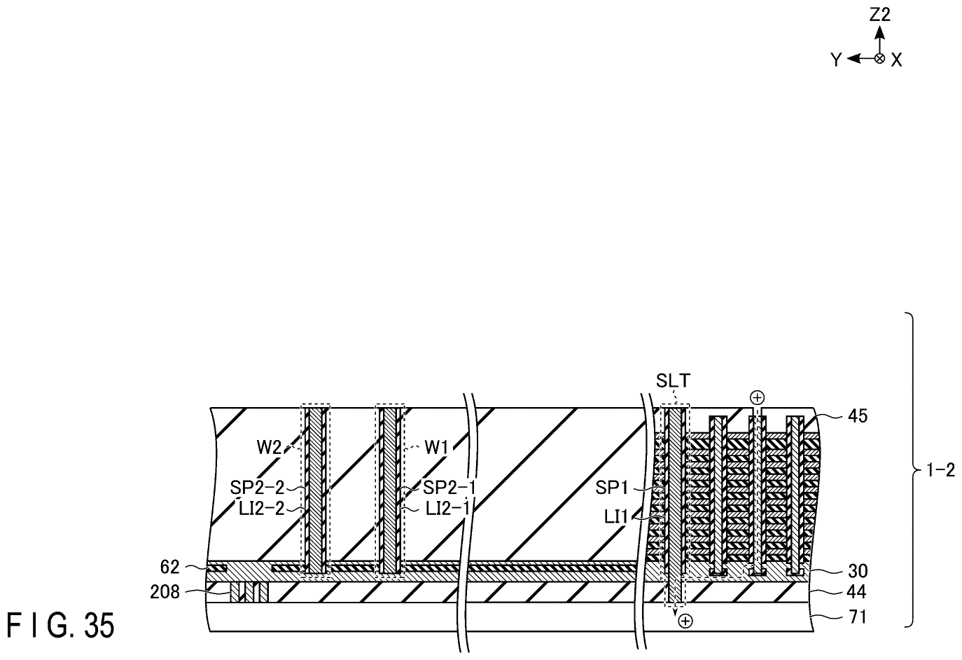

A method for manufacturing the semiconductor memory device 1 according to the second embodiment will be described with reference to FIGS. 34 and 35. FIGS. 34 and 35 are cross-sectional views for describing an example of a method for manufacturing the semiconductor memory device according to the second embodiment. The cross-sectional views illustrated in FIGS. 34 and 35 illustrate a region corresponding to FIG. 33.

In the second embodiment, the same processes as the processes of the first embodiment described with reference to FIGS. 12 and 13 are executed.

In addition, in the process corresponding to the process of the first embodiment described with reference to FIG. 14, as illustrated in FIG. 34, an insulating film SP corresponding to a spacer SP2, and the spacer SP1 are formed. More specifically, first, the insulating films SP corresponding to the spacers SP1 and SP2 are formed so as to cover the side surfaces and the first surface of a plurality of slits SH1 and SH2. Then, a mask MS2 in which regions corresponding to the plurality of slits SH1 are opened is formed. Then, a portion of the insulating film SP provided on the other side of the plurality of slits SH1 and a portion of the conductor layer 30A and the insulator layer 44 overlapping the portion in the Z direction are removed. As a result, the portion of the semiconductor substrate 71 is exposed on the other side of the plurality of slits SH1. In addition, the spacers SP1 are formed in the plurality of slits SH1.

Then, after the mask MS2 is removed, portions of the insulating films SP provided on the other side of the plurality of slits SH2 are removed. As a result, the portion of a conductor layer 30B is exposed on the other side of the plurality of slits SH2. In addition, the spacers SP2 are formed in the plurality of slits SH2.

Then, the plurality of contacts LI1 and LI2 is formed by the same process as the process of the first embodiment described with reference to FIG. 16. Thus, a plurality of members W and SLT is formed.

Next, similarly to the process of the first embodiment described with reference to FIG. 17, as illustrated in FIG. 35, regions of the insulator layer 45 on memory pillars MP where a plurality of conductor layers 35 is to be formed are collectively removed by anisotropic etching using a mask including openings corresponding to the plurality of conductor layers 35. In the second embodiment, in the present process, positive charges generated by the anisotropic etching are released to the semiconductor substrate 71 via, for example, a semiconductor film 51 of the memory pillar MP, the conductor layer 30A, and the plurality of members SLT.

Other processes are the same as those in the method for manufacturing the semiconductor memory device 1 according to the first embodiment.

The semiconductor memory device 1 is formed by the above-described manufacturing process.

The second embodiment also achieves effects equivalent to those of the first embodiment.

### 4 Modification of Second Embodiment

The above-described second embodiment can be variously modified. Hereinafter, a semiconductor memory device according to a modification of the second embodiment will be described.

In the second embodiment described above, the case where the contact LI1 integrally formed along the Z direction is in contact with the semiconductor substrate 71 in the manufacturing process has been described, but it is not limited thereto. The member SLT may include, for example, a configuration different from the portion of the contact LI1 made of a member containing metal at the same height as the insulator layer 44. Then, in the manufacturing process, the portion of the contact LI1 may be in contact with the semiconductor substrate 71 via the configuration portion. Hereinafter, a configuration and a manufacturing method of the semiconductor memory device 1 according to a modification of the second embodiment will be described in terms of differences from the configuration and the manufacturing method of the semiconductor memory device according to the second embodiment.

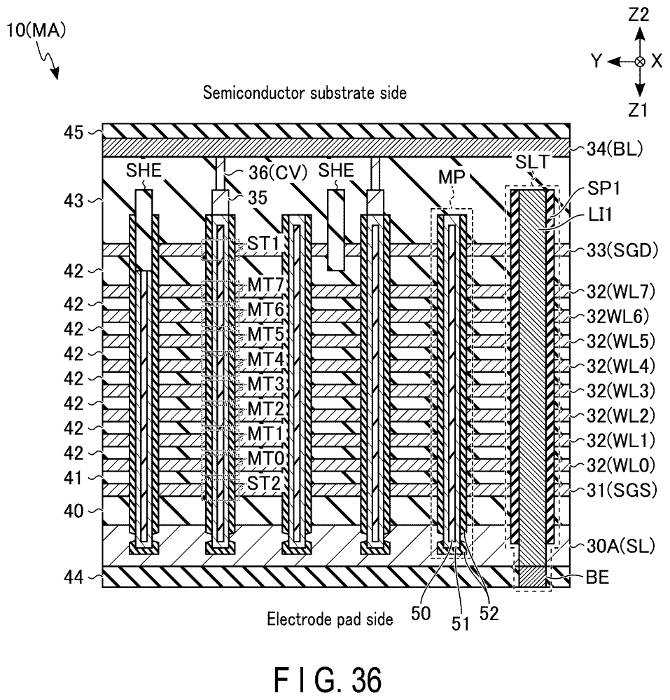

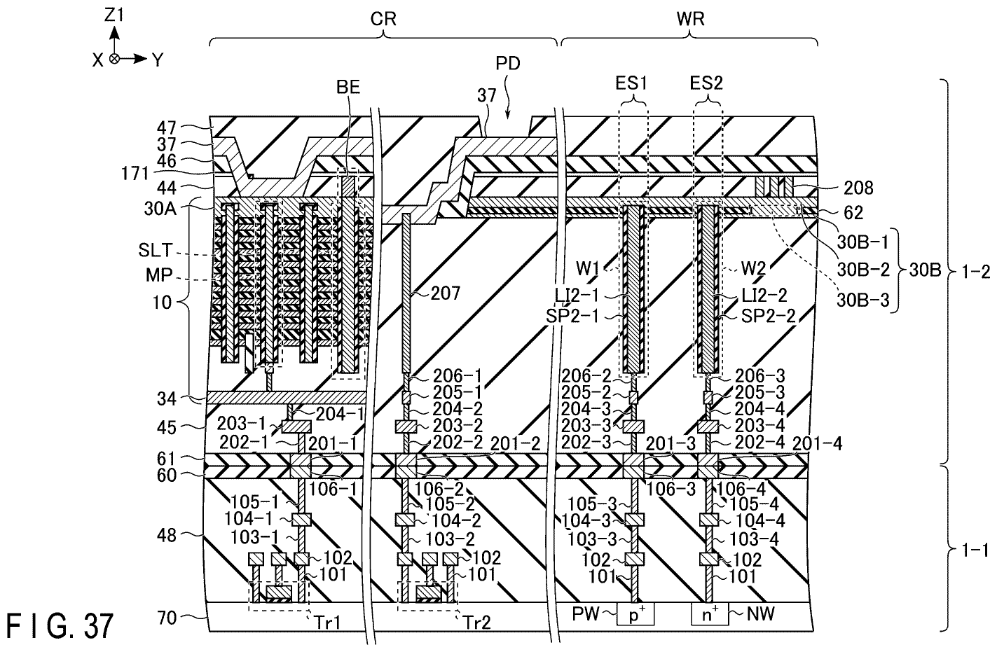

A configuration of the semiconductor memory device 1 according to the modification of the second embodiment will be described. Hereinafter, a cross-sectional structure of the memory cell array 10 and an overall cross-sectional structure of the semiconductor memory device 1 will be described with reference to FIGS. 36 and 37.

FIG. 36 is a cross-sectional view illustrating an example of a cross-sectional structure of the memory cell array of the semiconductor memory device according to the modification of the second embodiment. FIG. 37 is a cross-sectional view illustrating an example of a cross-sectional structure in a circuit region and a wall region of the semiconductor memory device according to the modification of the second embodiment. FIG. 37 illustrates a cross-sectional structure of a portion of the semiconductor memory device 1 corresponding to FIGS. 8 and 33.

In the modification of the second embodiment, the first surface of the contact LI1 is located between the first surface and the second surface of the insulator layer 44. However, it is not limited thereto, and as long as sufficient conduction can be obtained between the portion of the contact LI1 and the conductor layer 30A, the first surface of the contact LI1 may be located on one side in the Z direction with respect to the second surface of the insulator layer 44.

In addition, the member SLT further includes a contact portion BE. The contact portion BE is included in the same layer as the insulator layer 44, for example. The first surface of the contact portion BE is provided to be flush with the first surface of the insulator layer 44. As a result, the contact portion BE is in contact with the member 171, for example. Note that in a case where the semiconductor memory device 1 does not include the member 171, the first surface of the contact portion BE is in contact with, for example, the second surface of the insulator layer 46. The second surface of the contact portion BE is in contact with the first surface of the contact LI1. The contact portion BE is, for example, a silicon layer. The contact portion BE is, for example, an epitaxial layer. The contact portion BE is formed by epitaxial growth on the second surface of the semiconductor substrate 71 as described below.

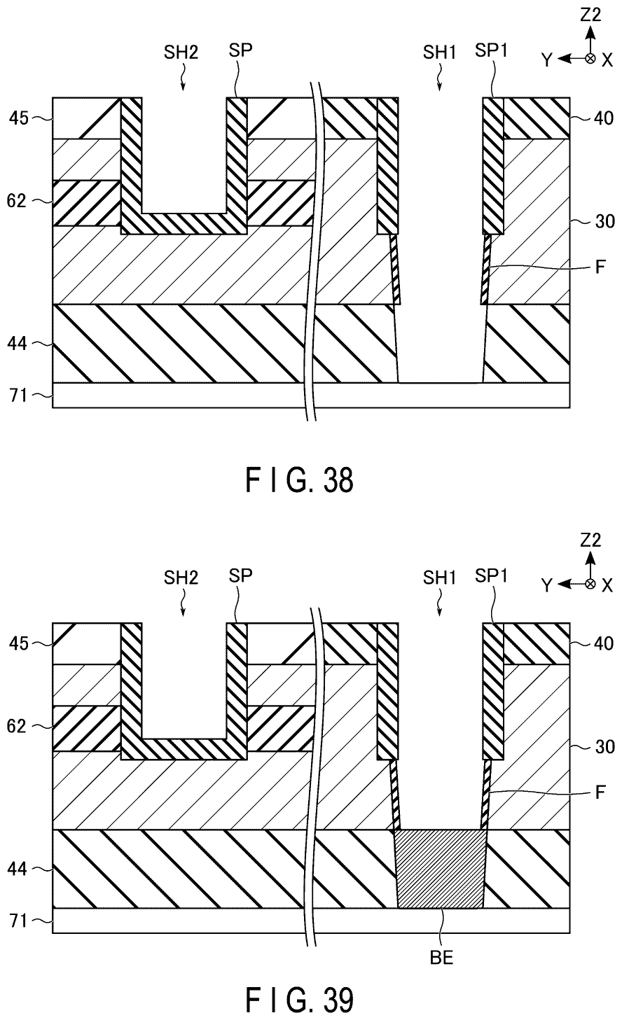

Next, a method for manufacturing the semiconductor memory device 1 according to the modification of the second embodiment will be described with reference to FIGS. 38 and 39. FIGS. 38 and 39 are cross-sectional views for describing an example of a method for manufacturing the semiconductor memory device according to the modification of the second embodiment.

After the process of the second embodiment described with reference to FIG. 34 and the removal of the mask MS2 are executed, and before the plurality of contacts LI1 and LI2 is formed, as illustrated in FIG. 38, a protective film F is formed on the portion of the conductor layer 30A exposed in the slit SH1. The protective film F is, for example, an oxide film formed by oxidation of the conductor layer 30A. As a result, formation of the epitaxial layer on the conductor layer 30A is suppressed.

Next, the contact portion BE is formed by epitaxial growth on the second surface of the semiconductor substrate 71 as illustrated in FIG. 39.

Then, after the protective film F and the portions of the insulating films SP provided on the other side of the plurality of slits SH2 are removed, the plurality of contacts LI1 and LI2 is formed. Thus, the plurality of members W and SLT is formed.

Other processes are the same as those in the method for manufacturing the semiconductor memory device 1 according to the second embodiment.

The semiconductor memory device 1 is formed by the above-described manufacturing process.

The modification of the second embodiment also achieves effects equivalent to those of the first embodiment.

In addition, according to the modification of the second embodiment, the semiconductor memory device 1 includes the contact portion BE provided so as to be in contact with the first surface of the contact LI1. Thus, the occurrence of scratches can be suppressed by not scraping the contact LI1. To supplement, in the manufacturing process, the contact portion BE is formed between the contact LI1 and the semiconductor substrate 71, so that the contact LI1 is suppressed from being partially removed together with the semiconductor substrate 71 in a case where at least a portion of the semiconductor substrate 71 is removed by CMP after the circuit chip 1-1 and the memory chip 1-2 are bonded together. Accordingly, since the contact LI1 that tends to cause scratches by polishing such as CMP is not a polishing target, the occurrence of scratches on the polished surface is suppressed.

### 5 Others

In the first embodiment and the first to fourth modifications of the first embodiment described above, the case where the member W includes only the contact LI2 as the conductor has been described, but it is not limited thereto. For example, as in the modification of the second embodiment, the same configuration as the contact portion BE may be provided on the surface on the other side in the Z direction of the contact LI2. That is, the member W may include a silicon layer such as an epitaxial layer. In addition, in the first embodiment, the first to fourth modifications of the first embodiment, the second embodiment, and the modification of the second embodiment, various combinations may be made without departing from the gist of the invention.

In the first embodiment, the first to fourth modifications of the first embodiment, the second embodiment, and the modification of the second embodiment described above, the case where the semiconductor memory device has a structure in which the circuit chip and the memory chip are bonded together has been described, but it is not limited thereto. The semiconductor memory device may be formed by, for example, one chip. Hereinafter, for the configuration of a semiconductor memory device according to another embodiment, a configuration different from those of the first embodiment, the first to fourth modifications of the first embodiment, the second embodiment, and the modification of the second embodiment will be described.

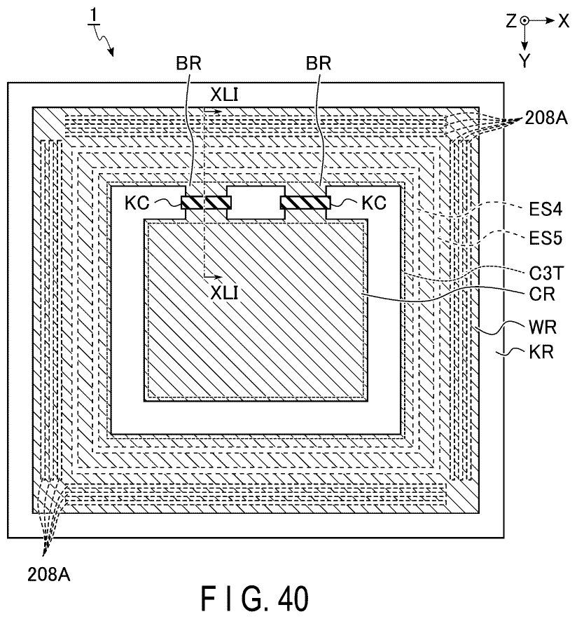

A planar layout of a semiconductor memory device 1 according to another embodiment will be described with reference to FIG. 40. FIG. 40 is a plan view illustrating an example of a planar layout of a semiconductor memory device according to another embodiment. As described above, the semiconductor memory device according to another embodiment is formed by one chip. Hereinafter, a direction from a semiconductor substrate toward a memory cell array is referred to as an upward direction. In addition, a direction from the memory cell array toward the semiconductor substrate is referred to as a downward direction.

The semiconductor memory device 1 according to another embodiment includes a circuit region CR, a contact region C3T, a wall region WR, and a kerf region KR. In another embodiment, sealing portions ES4 and ES5 are provided in the wall region WR. The sealing portions ES4 and ES5 correspond to the sealing portions ES1 and ES2 of the first embodiment.

The contact region C3T is a region between the circuit region CR and the wall region WR. In the contact region C3T, for example, a contact for coupling a memory cell array 10 and a peripheral circuit PERI is disposed.

In addition, one or more bridge regions BR are provided in the portion of the contact region C3T. In each bridge region BR, for example, a conductor layer included in the same layer as a source line SL is provided together with the wall region WR. In FIG. 40, a range in which the conductor layer and the source line SL are provided is indicated by hatching.

In addition, the semiconductor memory device 1 according to another embodiment further includes segment portions KC. The segment portion KC segments the source line SL and the conductor layer included in the same layer as the source line SL in each bridge region BR. As a result, the source line SL and the conductor layer of the wall region WR are electrically insulated.

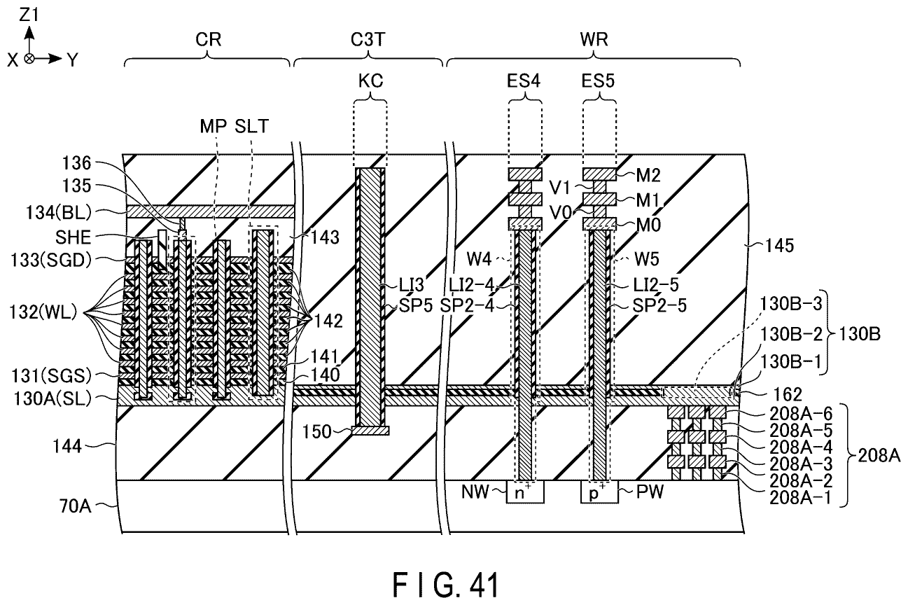

Next, a structure of the semiconductor memory device 1 according to another embodiment will be described with reference to FIG. 41. FIG. 41 is a cross-sectional view taken along line XLI-XLI of FIG. 40, illustrating an example of a cross-sectional structure in a circuit region and a wall region of the semiconductor memory device according to another embodiment.

The semiconductor memory device 1 further includes a semiconductor substrate 70A, conductor layers 130A, 130B, 131, and 133, a plurality of conductor layers 132, 134, 135, 136, and 208A, insulator layers 140, 141, 143, 144, 145, and 162, and a plurality of insulator layers 142. The conductor layers 130A, 130B, 131, and 133, the plurality of conductor layers 132, 134, 135, and 136, the insulator layers 140, 141, 143, 145, and 162, and the plurality of insulator layers 142 correspond to the conductor layers 30A, 30B, 31, and 33, the plurality of conductor layers 32, 34, 35, and 36, the insulator layers 40, 41, 43, 45, and 62, and the plurality of insulator layers 42, respectively. The memory cell array 10 according to another embodiment has substantially the same structure as the memory cell array according to the first embodiment.

The insulator layer 144 is provided on the upper surface of the semiconductor substrate 70A. The conductor layer 208A and the peripheral circuit PERI, which is not illustrated, are provided in the same layer as the insulator layer 144. The peripheral circuit PERI is provided in the circuit region CR. The conductor layer 208A penetrates the insulator layer 144 in the Z direction. The conductor layer 208A corresponds to the conductor layer 208.

The memory cell array 10 and the conductor layer 130B are provided on the upper surface of the insulator layer 144 and the conductor layer 208A. The memory cell array 10 is provided such that the conductor layer 130A (source line SL) is below the conductor layer 134 (bit line BL) in the circuit region CR. The conductor layer 130B is provided in the same layer as the conductor layer 130A. The insulator layer 162 is provided inside the conductor layer 130B. A portion of the conductor layer 130B included above the upper surface of the insulator layer 162 is referred to as a conductor portion 130B-1. A portion of the conductor layer 130B included below the lower surface of the insulator layer 162 is referred to as a conductor portion 130B-2. The conductor layer 130B includes a portion overlapping a region where the plurality of conductor layers 208A is provided in the Z direction. In the portion overlapping the plurality of conductor layers 208A in the Z direction, the insulator layer 162 is segmented by a conductor portion 130B-3 corresponding to the conductor portion 30B-3 of the first embodiment. The conductor portions 130B-1 and 130B-2 are electrically coupled by the conductor portion 130B-3.

In another embodiment, each of the plurality of conductor layers 208A includes conductor layers 208A-1, 208A-2, 208A-3, 208A-4, 208A-5, and 208A-6. Each of the conductor layers 208A-1 to 208A-6 functions as, for example, an annular contact or wiring.

The sealing portion ES4 includes a contact LI2-4 and a spacer SP2-4 as the contact LI2 and the spacer SP2, respectively. The sealing portion ES5 includes a contact LI2-5 and a spacer SP2-5 as the contact LI2 and the spacer SP2, respectively. The lower surface of the contact LI2-4 is in contact with, for example, an N-type impurity-diffused region NW provided in the semiconductor substrate 70A. The lower surface of the contact LI2-5 is in contact with, for example, a P-type impurity-diffused region PW provided in the semiconductor substrate 70A. Each spacer SP2 is provided so as to cover a side surface of a portion of the contact LI2 corresponding to the spacer SP2. The spacer SP2 is included, for example, above the lower surface of the conductor portion 130B-2. As a result, each contact LI2 is coupled to the conductor layer 130B. In each sealing portion ES, wiring and a contact can be provided on the upper surface of the contact LI2. In FIG. 41, in each sealing portion ES, wiring M0, a contact V0, wiring M1, a contact V1, and wiring M2 are provided in this order from the lower side to the upper side.

The segment portion KC includes, for example, a conductor layer 150, a contact LI3, and a spacer SP5. The conductor layer 150 is included in the insulator layer 144, for example. The contact LI3 is provided on the insulator layer 144. The contact LI3 is a conductor penetrating the conductor layer 130B and the insulator layer 162. The spacer SP5 is an insulator provided to cover the side surface of the contact LI3. As a result, the contact LI3 and the conductor layer 130B are electrically insulated. In addition, with the above configuration, the segment portion KC segments the conductor layer 130B and the insulator layer 162 in the bridge region BR. As a result, the conductor layer 130A and the conductor layer 130B in the wall region WR are electrically insulated from each other by the segment portion KC.

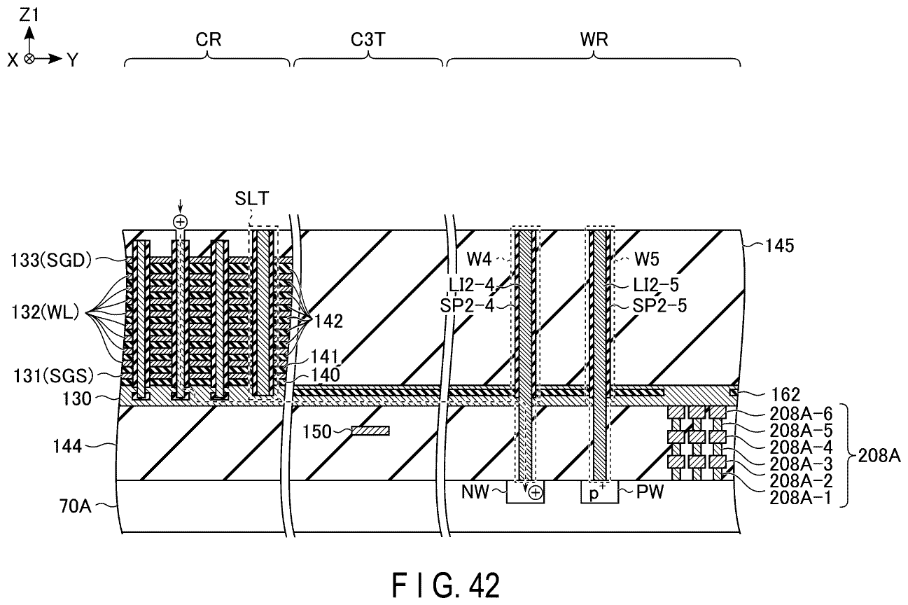

Next, a method for manufacturing the semiconductor memory device 1 according to another embodiment will be described with reference to FIG. 42. FIG. 42 is a cross-sectional view for describing an example of a method for manufacturing the semiconductor memory device according to another embodiment.

In the manufacturing process of the semiconductor memory device 1 according to another embodiment, the insulator layers 144 and 145, the portion of the memory cell array 10, the conductor layers 130B and 150, the insulator layer 162, the contact LI2, and the spacer SP2 are formed on the semiconductor substrate 70A. The portion of the memory cell array 10 includes the conductor layers 130A, 131, and 133, the plurality of conductor layers 132, the insulator layers 140 and 141, the plurality of insulator layers 142, memory pillars MP, and a member SLT. Note that the contact LI2 and the spacer SP2 are formed by, for example, substantially the same processes as the processes described with reference to FIGS. 12 to 16 in the first embodiment. In addition, in the present process, the conductor layer 130A and the conductor layer 130B in the wall region WR are electrically coupled to each other.

Next, as illustrated in FIG. 42, similarly to the process described with reference to FIG. 17, regions of the insulator layer 145 on the memory pillars MP where the plurality of conductor layers 135 is to be formed are collectively removed by anisotropic etching using a mask including openings corresponding to the plurality of conductor layers 135. The anisotropic etching in the present process is, for example, RIE. In the present process, positive charges generated by the anisotropic etching are released to the semiconductor substrate 70A via, for example, a semiconductor film of the memory pillar MP, the conductor layers 130A and 130B, and the plurality of members W.

Then, for example, after the plurality of conductor layers 134 to 136 is formed, the contact LI3 and the spacer SP5 of the segment portion KC are formed. As a result, the conductor layer 130B is separated by the segment portion KC. In addition, the conductor layer 130A and the conductor layer 130B in the wall region WR are electrically insulated from each other.

Such a configuration also achieves effects equivalent to those of the first embodiment.

The foregoing description of another embodiment has assumed a form of the sealing portion in which the Z1 direction end of the spacer and the Z1 direction end of the contact are aligned with each other, but the description does not intend any limitation to this form. The Z1 direction end of the spacer and the Z1 direction end of the contact may not be strictly aligned with each other. A description will be given of a configuration of the semiconductor memory device according to another embodiment which may be different from the configuration described above.

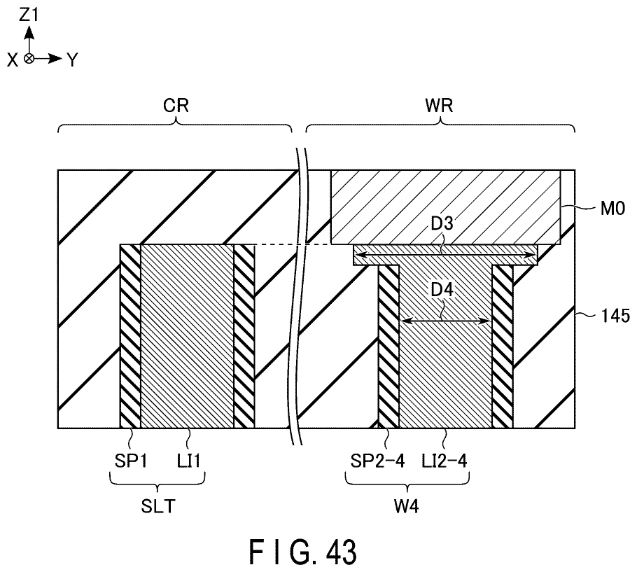

A configuration of the semiconductor memory device 1 according to another embodiment will be described with reference to FIG. 43. FIG. 43 is a cross-sectional view illustrating an example of a cross-sectional structure of a sealing portion and a member of the semiconductor memory device 1 according to another embodiment. FIG. 43 shows, as an example of the structure of the sealing portion ES, a structure of the Z1 direction portion of the member W4 of the sealing portion ES together with the Z1 direction portion of the member SLT.

In this sealing portion ES, one end on the Z1 direction side of the spacer SP2 is positioned on the semiconductor substrate 70A side with respect to a surface of the contact LI2 on the Z1 direction side. As such, the contact LI2 may include a slight portion in the Z direction of which side surface is not covered by the spacer SP2 on a more Z1 direction side than the spacer SP2. Here, for example, the portion of the contact LI2 that is positioned on a more Z1 direction side than the spacer SP2 has a Y direction width D3 which is larger than a Y direction width D4 of a portion of the contact LI2 that is covered by the spacer SP2. Also, for example, while not shown in the figure, the portion of the contact LI2 that is positioned on a more Z1 direction side than the spacer SP2 has an X direction width larger than an X direction width of the portion of the contact LI2 that is covered by the spacer SP2. Note that, as indicated by the dotted line in FIG. 43, the surface of the contact LI2 on the Z1 direction side is substantially at the same level in the Z direction as a surface of the member SLT on the Z1 direction side.

The semiconductor memory device 1 according to such another embodiment may be obtained based on a variation of the set-back amount in the CMP performed for removing the insulator layer 145 in which the conductors are embedded, in a process similar to the process described for the first embodiment with reference to FIG. 16.

Such a configuration also achieves effects equivalent to those of the first embodiment.

Note that the structure of the contact LI2 and the spacer SP2 of the sealing portion ES according to another embodiment is applicable to the first embodiment, the first to fourth modifications of the first embodiment, the second embodiment, and the modification of the second embodiment. For example, the contact LI2 of the sealing portion ES according to the first embodiment may include a portion on the Z2 direction side of which side surface is not covered by the spacer SP2 on a more Z2 direction side than the spacer SP2 as in the structure described with reference to FIG. 43. In this case, the portion of the contact LI2 that is positioned on a more Z2 direction side than the spacer SP2 has a Y direction width larger than a Y direction width of the portion of the contact LI2 that is covered by the spacer SP2.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a substrate that includes a first region and a second region provided so as to surround an outer periphery of the first region;
a memory cell array that is provided in the first region;
a first member that is provided in the second region; and
a first conductor portion that is provided so as to intersect the first member in the second region,
wherein
the memory cell array includes
a source line provided above the substrate,
a plurality of word lines provided apart from each other in a first direction above the substrate and on one side in the first direction intersecting a surface of the substrate with respect to the source line, and
a memory pillar provided to extend in the first direction so as to intersect the word lines and having one end in the first direction coupled to the source line,
the first conductor portion is included in a same layer as the source line, includes a surface on an other side in the first direction having a height substantially equivalent to a height of a surface on the other side in the first direction of the source line, and is electrically insulated from the source line, and
the first member includes
a first contact extending in the first direction so as to surround the word lines at least in a range substantially equivalent to the word lines in the first direction while being separated from the word lines, reaching the other side in the first direction with respect to a first height of the surface on the other side of the first conductor portion, and integrally provided along the first direction, and
a first insulating film covering a side surface of the first contact from a second height approximately equivalent to a height of one end of the first contact on the one side in the first direction to a third height on the one side in the first direction with respect to an other end of the first contact in the first direction, and forming an end on the other side in the first direction at the third height.

2. The semiconductor memory device according to claim 1, wherein
the first contact
reaches the other side in the first direction with respect to the first height in a first sub-region in the second region, and
is provided on the one side in the first direction with respect to the first height in a second sub-region in the second region.

3. The semiconductor memory device according to claim 1, wherein the first contact is provided so as to surround the first region.

4. The semiconductor memory device according to claim 3, wherein in the first contact, a portion included on the other side in the first direction with respect to the first height is continuously provided so as to surround the first region.

5. The semiconductor memory device according to claim 1 further comprising:
a second conductor portion that is electrically insulated from the source line and included in a same layer as the source line on the one side in the first direction with respect to the first conductor portion; and
a first insulator layer that is provided between the first conductor portion and the second conductor portion in the first direction and in contact with the first conductor portion and the second conductor portion.

6. The semiconductor memory device according to claim 5, wherein
the first contact
intersects the first conductor portion and the second conductor portion, and is electrically coupled to the first conductor portion.

7. The semiconductor memory device according to claim 5, wherein the third height is located on the other side in the first direction with respect to the second conductor portion.

8. The semiconductor memory device according to claim 5, wherein
the first member further includes
a second insulating film provided so as to cover the side surface of the first contact on the other side in the first direction with respect to the third height,
the third height is substantially equivalent to a fourth height of a surface of the first insulator layer on the other side in the first direction, or is located on the other side in the first direction with respect to the fourth height, and
the first contact is
in contact with the first conductor portion between the first insulating film and the second insulating film in a direction parallel to the surface of the substrate.

9. The semiconductor memory device according to claim 1, further comprising:
a second member that is provided in the second region and intersects the first conductor portion,
wherein
the second member includes
a second contact extending in the first direction so as to surround the word lines at least in the range substantially equivalent to the word lines in the first direction while being separated from the word lines, reaching the other side in the first direction with respect to the first height, and integrally provided along the first direction, and
a third insulating film covering a side surface of the second contact from a fifth height approximately equivalent to a height of one end of the second contact on the one side in the first direction to a sixth height on the one side in the first direction with respect to an other end of the second contact in the first direction, and forming an end on the other side in the first direction at the sixth height.

10. The semiconductor memory device according to claim 1, wherein
the substrate is provided in a first chip, and
the memory cell array, the first member, and the first conductor portion are provided in a second chip in contact with the first chip in the first direction,
the device further comprising:
a plurality of first connection pads that is provided in a boundary region between the first chip and the second chip.

11. The semiconductor memory device according to claim 10, wherein an other end of the memory pillar in the first direction is coupled to any one of the first connection pads via a conductor layer.

12. The semiconductor memory device according to claim 10, wherein the one end of the first contact is coupled to any one of the first connection pads via a conductor layer.

13. The semiconductor memory device according to claim 1, wherein the other end of the first contact is in contact with the substrate.

14. The semiconductor memory device according to claim 13, further comprising:
a first wiring layer that is provided on the one side in the first direction with respect to the memory pillar and extends in a direction parallel to the surface of the substrate,
wherein
an other end of the memory pillar in the first direction is coupled to the first wiring layer via a conductor layer.

15. The semiconductor memory device according to claim 1, wherein the first contact is electrically coupled to a P-type or N-type impurity-diffused region included in the substrate.

16. The semiconductor memory device according to claim 1, further comprising:
a second contact that is provided on an outer peripheral side of the first member in a direction parallel to the surface of the substrate so as to surround the word lines when viewed in the first direction, the second contact being in contact with the surface on the other side of the first conductor portion.

17. The semiconductor memory device according to claim 1, wherein the one end of the first contact is located on the one side in the first direction with respect to an other end of the memory pillar in the first direction.

18. A semiconductor memory device comprising:
a first chip that includes a substrate; and
a second chip that is in contact with the first chip in a first direction intersecting a surface of the substrate,
wherein
the second chip includes
a memory cell array including a source line, a plurality of word lines provided below the source line and apart from each other in the first direction, and a memory pillar extending in the first direction so as to intersect the word lines and having an upper end coupled to the source line, and
a first member extending in a second direction in the surface of the substrate in the word lines and dividing the word lines in a third direction in the surface of the substrate intersecting the second direction,
and
the first member includes
a first contact extending in the first direction and including a portion located above the source line, and
a first insulating film provided to cover a side surface of the first contact from a first height approximately equivalent to a height of a lower end of the first contact to a second height between an upper surface and a lower surface of the source line.

19. The semiconductor memory device according to claim 18, wherein
the first contact includes a first portion and a second portion provided on the first portion on an upper side in the first direction and made of a material different from a material of the first portion, and
the second portion is a silicon layer.

20. A semiconductor memory device comprising:
a first chip that includes a substrate including a first region and a second region provided so as to surround an outer periphery of the first region; and
a second chip that is in contact with the first chip in a first direction intersecting a surface of the substrate,
wherein
the second chip includes
a memory cell array including, in the first region, a source line, a plurality of word lines provided below the source line and apart from each other in the first direction, and a memory pillar extending in the first direction so as to intersect the word lines and having an upper end coupled to the source line,
a first member including a first contact extending in the first direction at least in a range substantially equivalent to the word lines in the first direction,
a first conductor portion included in a same layer as the source line, having an upper surface with a height substantially equivalent to a height of an upper surface of the source line, and electrically insulated from the source line, and
a second member provided on an outer peripheral side of the word lines and the first member in a direction parallel to the surface of the substrate in the second region so as to surround the word lines when viewed in the first direction, the second member being in contact with the upper surface of the first conductor portion, and
the first contact includes
a portion located above the upper surface of the source line.
